(19) United States
(12) Patent Application Publication
(10) Pub. No.: US 2026/0123153 A1
(43) Pub. Date: Apr. 30, 2026

(54) DISPLAY DEVICE, METHOD OF MANUFACTURING THE DISPLAY DEVICE, AND ELECTRONIC DEVICE

(71) Applicant: Samsung Display Co., LTD., Yongin-si (KR)

(72) Inventors: Chang Hun LEE, Yongin-si (KR); Tae Hoon KIM, Yongin-si (KR); Kang Seob JEONG, Yongin-si (KR)

(73) Assignee: Samsung Display Co., LTD., Yongin-si (KR)

(21) Appl. No.: 19/220,394

(22) Filed: May 28, 2025

(30) Foreign Application Priority Data
Oct. 30, 2024 (KR) 10-2024-0150952

(51) Int. Cl. H10H 29/851; H10H 29/01; H10H 29/37; H10H 29/45; H10H 29/85; H10H 29/853; H10K 59/12; H10K 59/122; H10K 59/127; H10K 59/38; H10K 59/80

(52) U.S. Cl. CPC H10H 29/8511; H10H 29/012; H10H 29/0361; H10H 29/37; H10H 29/45; H10H 29/8517; H10H 29/853; H10K 59/1201; H10K 59/122; H10K 59/127; H10K 59/38; H10K 59/873

(57) ABSTRACT

Provided is a display device including a light emitting element layer disposed on a substrate, a thin-film encapsulation layer disposed on the light emitting element layer, a counter substrate facing the substrate, a color filter layer disposed on a surface of the counter substrate and having light transmitting areas and a light blocking area defined, a wavelength conversion layer disposed on the color filter layer, and a filling layer disposed between the wavelength conversion layer and the thin-film encapsulation layer, wherein the wavelength conversion layer includes, a bank overlapping the light blocking area, light transmitting members disposed between portions of the bank and spaced apart from each other, and organic layers spaced apart from each other with the bank interposed between the organic layers and covering the light transmitting members, and lower surfaces of the organic layers and a lower surface of the bank are disposed on a same layer.

### CROSS-REFERENCE TO RELATED APPLICATION(S)

This application claims priority to and benefits of Korean Patent Application No. 10-2024-0150952 under 35 U.S.C. § 119, filed on Oct. 30, 2024, in the Korean Intellectual Property Office, the entire contents of which are incorporated herein by reference.

### BACKGROUND

### 1. Technical Field

The disclosure relates to a display device, a method of manufacturing the display device, and an electronic device.

### 2. Description of the Related Art

As the information society is sophisticated and developed, demands for display devices for displaying images are increasing in various forms. For example, display devices are applied to various electronic devices such as smartphones, digital cameras, laptop computers, navigation devices, and smart televisions.

The display devices may be flat panel display devices such as liquid crystal display devices, field emission display devices, and light emitting display devices. The light emitting display devices may include an organic light emitting display device including an organic light emitting element, an inorganic light emitting display device including an inorganic light emitting element such as an inorganic semiconductor, and an ultrasmall light emitting display device including an ultrasmall light emitting element.

The organic light emitting element may include two electrodes facing each other and a light emitting layer interposed between them. The light emitting layer may receive electrons and holes from the two electrodes, recombine them to generate excitons, and emit light as the generated excitons change from an excited state to a ground state.

Since the organic light emitting display device including the organic light emitting element does not need a light source such as a backlight unit, it is low in power consumption, can be made lightweight and thin, and has a wide viewing angle, high luminance and contrast, and fast response speed. Due to these high-quality characteristics, the organic emitting display device is drawing attention as a next-generation display device.

### SUMMARY

Aspects of the disclosure provide a display device which can solve the problem of a residual perfluorinated compound and improve display quality, a method of manufacturing the display device, and an electronic device.

However, aspects of the disclosure are not restricted to the one set forth herein. The above and other aspects of the disclosure will become more apparent to one of ordinary skill in the art to which the disclosure pertains by referencing the detailed description of the disclosure given below.

According to an aspect of the disclosure, a display device includes a light emitting element layer disposed on a substrate, a thin-film encapsulation layer disposed on the light emitting element layer, a counter substrate facing the substrate, a color filter layer disposed on a surface of the counter substrate and having a plurality of light transmitting areas and a light blocking area defined, a wavelength conversion layer disposed on the color filter layer, and a filling layer disposed between the wavelength conversion layer and the thin-film encapsulation layer, wherein the wavelength conversion layer includes, a bank overlapping the light blocking area, a plurality of light transmitting members disposed between portions of the bank and spaced apart from each other, and organic layers spaced apart from each other with the bank interposed between the organic layers and covering the light transmitting members, and lower surfaces of the organic layers and a lower surface of the bank are disposed on a same layer.

In an embodiment, the bank and the organic layers may contact the filling layer.

In an embodiment, the organic layers may overlap the light transmitting areas and may not overlap the light blocking area.

In an embodiment, a refractive index of each of the organic layers may be about 1.7 or less.

In an embodiment, the bank may be non-hydrophobic.

In an embodiment, the display device may further include a first capping layer overlapping the organic layers and the bank.

In an embodiment, upper surfaces of the organic layers may contact the light transmitting members, respectively, and the lower surfaces of the organic layers may contact the first capping layer.

In an embodiment, the first capping layer may be formed flat.

In an embodiment, the display device may further include a second capping layer disposed between the light transmitting members and the organic layers and covering the light transmitting members.

In an embodiment, the display device may further include third capping layers spaced apart from each other with the bank disposed between the third capping layers and extend along side surfaces of the bank.

In an embodiment, the organic layers may be surrounded by the first capping layer and the third capping layer.

In an embodiment, the display device may further include a first capping layer disposed between the light transmitting members and the organic layers and covering the light transmitting members.

In an embodiment, the first capping layer may be formed in plural, spaced apart from each other with the bank interposed therebetween and extend along side surfaces of the bank.

According to an aspect of the disclosure, a method of manufacturing a display device, the method includes forming a bank on a first substrate, forming a hydrophobic layer on an upper surface of the bank by performing an ashing process and a plasma process on the bank, forming a plurality of light transmitting members between portions of the bank, forming an organic material layer on the bank and the light transmitting members, forming organic layers by removing a portion of the organic material layer and the hydrophobic layer, forming a filling layer on the bank and the organic layers, and bonding the first substrate to a second substrate facing the first substrate.

In an embodiment, the ashing process may be a plasma treatment process using Ar, N₂, He, O₂, or a mixed gas thereof as a reaction gas.

In an embodiment, the plasma process may use a CF₄ gas.

In an embodiment, the method may further include forming a first capping layer on the bank and the light transmitting members before the forming of the organic material layer, wherein a portion of the first capping layer may be removed at same time as the portion of the organic material layer and the hydrophobic layer are removed.

In an embodiment, the method may further include forming a second capping layer on the bank and the organic layers before the forming of the filling layer.

In an embodiment, the method may further include forming a color filter layer on the first substrate before the forming of the bank, wherein the second substrate may include a light emitting element layer including a plurality of light emitting elements and a thin-film encapsulation layer formed on the light emitting element layer, and the bank may be formed on the color filter layer.

In an embodiment, the method may further include forming a color filter layer on the second substrate before the forming of the bank, wherein the first substrate may include a light emitting element layer including a plurality of light emitting elements and a thin-film encapsulation layer formed on the light emitting element layer, and the bank may be formed on the thin-film encapsulation layer.

According to an aspect of the disclosure, an electronic device includes a display device which provides an image, a processor which provides an image data signal to the display device, a memory which stores a data information for operation, and a power module which generates power, wherein the display device includes, a light emitting element layer disposed on a substrate, a thin-film encapsulation layer disposed on the light emitting element layer, a counter substrate facing the substrate, a color filter layer disposed on a surface of the counter substrate and having a plurality of light transmitting areas and a light blocking area defined, a wavelength conversion layer disposed on the color filter layer, and a filling layer disposed between the wavelength conversion layer and the thin-film encapsulation layer, wherein the wavelength conversion layer includes, a bank overlapping the light blocking area, a plurality of light transmitting members disposed between portions of the bank and spaced apart from each other, and organic layers spaced apart from each other with respect to the bank interposed between the organic layers and covering the light transmitting members, and lower surfaces of the organic layers and a lower surface of the bank are disposed on a same layer.

### BRIEF DESCRIPTION OF THE DRAWINGS

These and/or other aspects will become apparent and more readily appreciated from the following description of the embodiments, taken in conjunction with the accompanying drawings in which:

FIG. 1 is a schematic plan view of a display device according to an embodiment;

FIG. 2 is a schematic layout view illustrating lines included in the display device according to the embodiment;

FIG. 3 is a schematic diagram of an equivalent circuit of a subpixel according to an embodiment;

FIG. 4 is a schematic cross-sectional view of the display device according to the embodiment;

FIG. 5 is a schematic cross-sectional view of the display device according to the embodiment;

FIGS. 6 through 12 are schematic cross-sectional views illustrating each process in a method of manufacturing a display device according to an embodiment;

FIG. 13 is a schematic cross-sectional view of a display device according to an embodiment;

FIGS. 14 through 17 are schematic cross-sectional views illustrating each process in a method of manufacturing a display device according to an embodiment;

FIG. 18 is a schematic cross-sectional view of a display device according to an embodiment;

FIG. 19 is a schematic cross-sectional view of a display device according to an embodiment;

FIGS. 20 through 25 are schematic cross-sectional views illustrating each process in a method of manufacturing a display device according to an embodiment;

FIG. 26 is a schematic cross-sectional view of a display device according to an embodiment;

FIGS. 27 through 30 are schematic cross-sectional views illustrating each process in a method of manufacturing a display device according to an embodiment;

FIG. 31 is a schematic cross-sectional view of a display device according to an embodiment;

FIG. 32 is a schematic diagram showing images of ink formed according to Experimental Example 1;

FIG. 33 is a schematic diagram showing images of ink formed according to Experimental Example 2;

FIGS. 34 and 35 are schematic diagrams showing images and sizes of ink drops on samples according to Experimental Example 3 and surface energy of a bank surface;

FIG. 36 is a schematic block diagram of an electronic device according to one embodiment of the disclosure; and

FIG. 37 is a schematic diagram of an electronic device according to various embodiments of the disclosure.

### DETAILED DESCRIPTION OF THE EMBODIMENTS

In the following description, for the purposes of explanation, numerous specific details are set forth in order to provide a thorough understanding of various embodiments or implementations of the disclosure. As used herein “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in another embodiment.

Unless otherwise specified, the illustrated embodiments are to be understood as providing features of the disclosure. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the scope of the disclosure.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals and/or reference characters denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the axis of the first direction DR1, the axis of the second direction DR2, and the axis of the third direction DR3 are not limited to three axes of a rectangular coordinate system, such as the X, Y, and Z-axes, and may be interpreted in a broader sense. For example, the axis of the first direction DR1, the axis of the second direction DR2, and the axis of the third direction DR3 may be perpendicular to one another, or may represent different directions that are not perpendicular to one another. For the purposes of this disclosure, “at least one of A and B” may be construed as A only, B only, or any combination of A and B. Also, “at least one of X, Y, and Z” and “at least one selected from the group consisting of X, Y, and Z” may be construed as X only, Y only, Z only, or any combination of two or more of X, Y, and Z. As used herein, the term “and/or” includes any and all combinations of one or more of the associated listed items.

Although the terms “firstly,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one element's relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art. For example, “about” may mean within one or more standard deviations, or within ±20%, ±10%, or ±5% of the stated value.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

As customary in the field, some embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (e.g., microcode) to perform various functions discussed herein and may optionally be driven by firmware and/or software. It is also contemplated that each block, unit, and/or module may be implemented by dedicated hardware, or as a combination of dedicated hardware to perform some functions and a processor (e.g., one or more programmed microprocessors and associated circuitry) to perform other functions. Also, each block, unit, and/or module of some embodiments may be physically separated into two or more interacting and discrete blocks, units, and/or modules without departing from the scope of the disclosure. Further, the blocks, units, and/or modules of some embodiments may be physically combined into more complex blocks, units, and/or modules without departing from the scope of the disclosure.

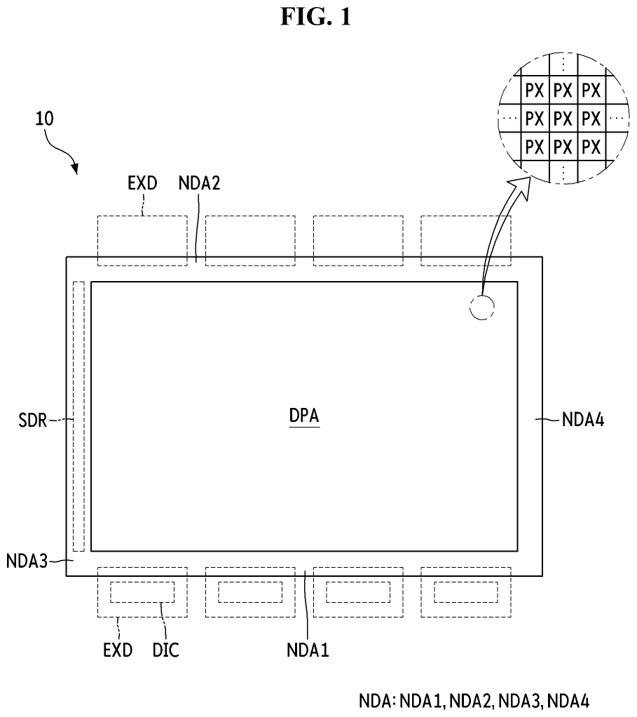

FIG. 1 is a schematic plan view of a display device 10 according to an embodiment.

Referring to FIG. 1, the display device 10 according to the embodiment may be applied to various electronic devices such as smartphones, mobile phones, tablet personal computers (PCs), personal digital assistants (PDAs), portable multimedia players (PMPs), televisions, game consoles, wristwatch-type electronic devices, head mounted displays, monitors of PCs, laptop computers, car navigation systems, car dashboards, digital cameras, camcorders, outdoor billboards, electronic display boards, medical devices, examination devices, refrigerators, and washing machines. The display device 10 disclosed in the present specification may be included in the above electronic devices, and a television will be described as an example of the display device 10. The television may have high resolution or ultra-high resolution such as HD, UHD, 4K, or 8K.

The display device 10 according to the embodiment may be variously classified according to a display method. For example, the display device 10 may be classified as an organic light emitting display device, an inorganic electroluminescent (EL) display device, a quantum dot light emitting display device (QED), a micro-light emitting diode display device, a nano-light emitting diode display device, a plasma display panel (PDP), a field emission display (FED) device, a cathode ray tube (CRT) display device, a liquid crystal display (LCD) device, or an electrophoretic display (EPD) device. An organic light emitting display device and an inorganic EL display device will be described below as examples of the display device 10. Unless a special distinction is required, the display devices applied to embodiments will be simply shortened to display devices. However, the embodiments are not limited to the organic light emitting display device or the inorganic EL display device, and other display devices listed above or known in the art can also be applied within the scope sharing the technical spirit.

The display device 10 according to the embodiment may have a quadrate shape, for example, a rectangular shape in a plan view. In case that the display device 10 is a television, its long sides are located in a horizontal direction. However, the disclosure is not limited thereto, and the long sides may also be located in a vertical direction, or the display device 10 may be rotatably installed so that the long sides can be variably located in the horizontal or vertical direction.

The display device 10 may include a display area DPA and a non-display area NDA. The display area DPA may be an active area in which an image is displayed. The display area DPA may have a rectangular shape similar to the overall shape of the display device 10 in a plan view, but the disclosure is not limited thereto.

The display area DPA may include multiple pixels PX. The pixels PX may each include multiple subpixels and may be arranged in a matrix direction. Each subpixel may be rectangular or square in a plan view. However, the disclosure is not limited thereto, and each subpixel may also have a rhombus shape having each side inclined with respect to a side of the display device 10. The subpixels may emit light of various colors. For example, the subpixels may include, but are not limited to, a subpixel emitting red light, a subpixel emitting green light, and a subpixel emitting blue light. The subpixels may be alternately arranged in a stripe type or a Pentile® type.

The non-display area NDA may be located around the display area DPA. The non-display area NDA may entirely or partially surround the display area DPA. The display area DPA may be rectangular, and the non-display area NDA may be adjacent to four sides of the display area DPA. The non-display area NDA may form a bezel of the display device 10.

Driving circuits or driving elements for driving the display area DPA may be located in the non-display area NDA. A pad unit may be provided on a display substrate of the display device 10 in a first non-display area NDA1 located adjacent to a first long side (e.g., a lower side in FIG. 1) of the display device 10 and a second non-display area NDA2 located adjacent to a second long side (e.g., an upper side in FIG. 1), and external devices EXD may be mounted on pad electrodes of the pad unit. Examples of the external devices EXD may include connection films, printed circuit boards, driving chips DIC, connectors, and wiring connection films. A scan driver SDR formed directly on the display substrate of the display device 10 may be located in a third non-display area NDA3 located adjacent to a first short side (e.g., a left side in FIG. 1) of the display device 10. In another example, the scan driver SDR may be located in a fourth non-display area NDA4 opposite to the third non-display area NDA3. However, the disclosure is not limited thereto, and the scan driver SDR may also be disposed on a second short side (e.g., a right side in FIG. 1) of the display device 10.

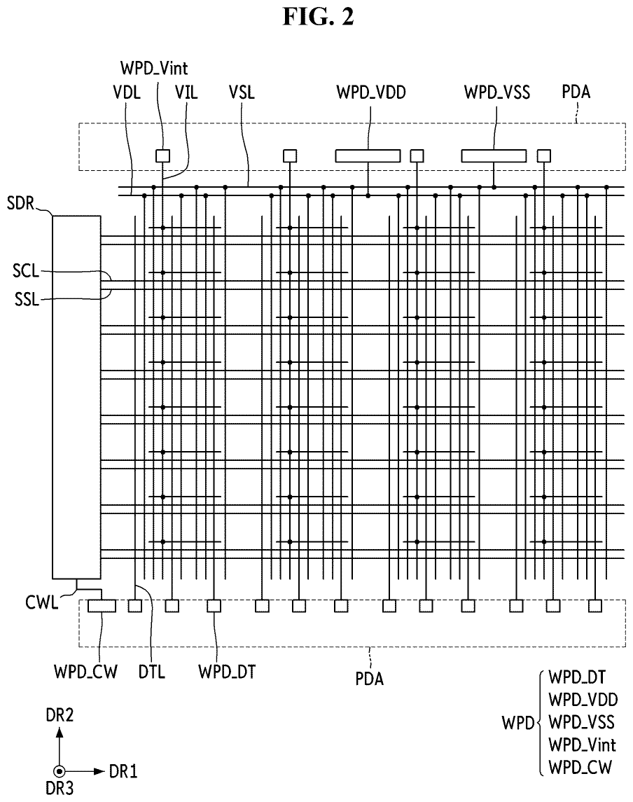

FIG. 2 is a schematic layout view illustrating lines included in the display device 10 according to the embodiment.

Referring to FIG. 2, the display device 10 may include multiple lines. The lines may include scan lines SCL, sensing lines SSL, data lines DTL, initialization voltage lines VIL, a first voltage line VDL, and a second voltage line VSL. Although not illustrated in the drawing, other lines may be further located in the display device 10.

The scan lines SCL and the sensing signal lines SSL may extend in a first direction DR1. The scan lines SCL and the sensing signal lines SSL may be electrically connected to the scan driver SDR. The scan driver SDR may include a driving circuit. The scan driver SDR may be disposed on a side of the display area DPA in the first direction DR1, but the disclosure is not limited thereto. The scan driver SDR may be electrically connected to a signal connection line CWL, and at least one end of the signal connection line CWL may form a pad WPD_CW in a pad area PDA of the non-display area NDA and may be electrically connected to an external device.

As used herein, the term “connect” may mean that any one member and another member are connected to each other not only through physical contact but also through another member. It can be understood that any one part and another part are connected to each other as one integrated member. Further, the connection between any one member and another member can be interpreted to include electrical connection through another member in addition to connection through direct contact.

The data lines DTL and the initialization voltage lines VIL may extend in a second direction DR2 intersecting the first direction DR1. Each of the initialization voltage lines VIL may include a portion extending in the second direction DR2 and may further include portions branching from the above portion in the first direction DR1. Each of the first voltage line VDL and the second voltage line VSL may also include portions extending in the second direction DR2 and a portion electrically connected to the above portions and extending in the first direction DR1. The first voltage line VDL and the second voltage line VSL may have a mesh structure, but the disclosure is not limited thereto. Although not illustrated in the drawing, each pixel PX of the display device 10 may be electrically connected to at least one data line DTL, an initialization voltage line VIL, the first voltage line VDL, and the second voltage line VSL.

The data lines DTL, the initialization voltage lines VIL, the first voltage line VDL, and the second voltage line VSL may be electrically connected to one or more wiring pads WPD. Each wiring pad WPD may be located in the pad area PDA. In an embodiment, wiring pads WPD_DT (hereinafter, referred to as ‘data pads’) of the data lines DTL may be located in a pad area PDA on a side of the display area DPA in the second direction DR2, and wiring pads WPD_Vint (hereinafter, referred to as ‘initialization voltage pads’) of the initialization voltage lines VIL, a wiring pad WPD_VDD (hereinafter, referred to as a ‘first power pad’) of the first voltage line VDL, and a wiring pad WPD_VSS (hereinafter, referred to as a ‘second power pad’) of the second voltage line VSL may be located in a pad area PDA disposed on another side of the display area DPA in the second direction DR2. For another example, the data pads WPD_DT, the initialization voltage pads WPD_Vint, the first power pad WPD_VDD, and the second power pad WPD_VSS may all be located in the same area, for example, in the non-display area NDA disposed on an upper side of the display area DPA. The external devices EXD may be mounted on the wiring pads WPD. The external devices EXD may be mounted on the wiring pads WPD through anisotropic conductive films, ultrasonic bonding, or the like.

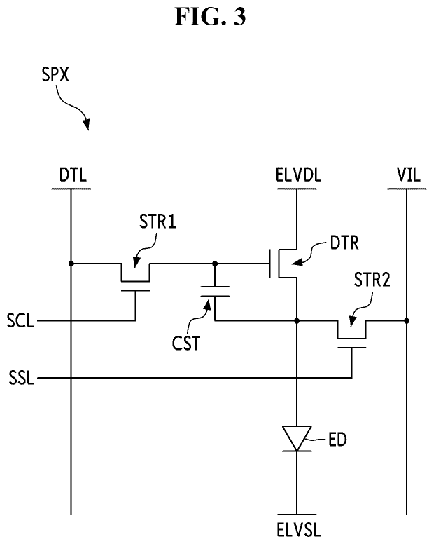

Multiple subpixels SPX (see FIG. 3) included in each pixel PX of the display device 10 may include a pixel driving circuit. The above-described lines may transmit driving signals to each pixel driving circuit while passing through or around each subpixel SPX. The pixel driving circuit may include a transistor and a capacitor. The number of transistors and capacitors in each pixel driving circuit can be variously changed. According to an embodiment, the pixel driving circuit of each subpixel SPX of the display device 10 may have a 3T1C structure including three transistors and one capacitor. Although the pixel driving circuit is described below using the 3T1C structure as an example, the disclosure is not limited thereto, and other various modified pixel structures such as a 2T1C structure, a 7T1C structure, and a 6T1C structure are also applicable.

FIG. 3 is a schematic diagram of an equivalent circuit of a subpixel SPX according to an embodiment.

Referring to FIG. 3, each subpixel SPX of the display device 10 according to the embodiment may include three transistors DTR, STR1 and STR2 and one storage capacitor CST in addition to a light emitting element ED.

The light emitting element ED may emit light according to a current supplied through a driving transistor DTR. The light emitting element ED may be implemented as an inorganic light emitting diode, an organic light emitting diode, a micro-light emitting diode, or a nano-light emitting diode.

A first electrode (i.e., an anode) of the light emitting element ED may be electrically connected to a source electrode of the driving transistor DTR, and a second electrode (i.e., a cathode) may be electrically connected to a second power line ELVSL to which a low potential voltage (or a second power supply voltage) lower than a high potential voltage (or a first power supply voltage) of a first power line ELVDL is supplied.

The driving transistor DTR may adjust a current flowing from the first power line ELVDL, to which the first power supply voltage is supplied, to the light emitting element ED according to a voltage difference between a gate electrode and the source electrode. The driving transistor DTR may have the gate electrode connected to a first electrode of a first transistor STR1, the source electrode connected to the first electrode of the light emitting element ED, and a drain electrode connected to the first power line ELVDL to which the first power supply voltage is applied.

The first transistor STR1 may be turned on by a scan signal of a scan line SCL to connect a data line DTL to the gate electrode of the driving transistor DTR. The first transistor STR1 may have a gate electrode connected to the scan line SCL, the first electrode connected to the gate electrode of the driving transistor DTR, and a second electrode connected to the data line DTL.

A second transistor STR2 may be turned on by a sensing signal of a sensing signal line SSL to connect an initialization voltage line VIL to the source electrode of the driving transistor DTR. The second transistor STR2 may have a gate electrode connected to the sensing signal line SSL, a first electrode connected to the initialization voltage line VIL, and a second electrode connected to the source electrode of the driving transistor DTR.

The first electrode of each of the first and second transistors STR1 and STR2 may be a source electrode, and the second electrode may be a drain electrode. However, the disclosure is not limited thereto, and the opposite may also be the case.

The storage capacitor CST may be formed between the gate electrode and the source electrode of the driving transistor DTR. The storage capacitor CST may store a difference between a gate voltage and a source voltage of the driving transistor DTR.

The driving transistor DTR and the first and second transistors STR1 and STR2 may be formed as thin-film transistors. Although a case where the driving transistor DTR and the first and second switching transistors STR1 and STR2 are N-type metal oxide semiconductor field effect transistors (MOSFETs) has been mainly described in FIG. 3, the disclosure is not limited thereto. For example, the driving transistor DTR and the first and second switching transistors STR1 and STR2 may also be formed as P-type MOSFETs, or some of them may be formed as N-type MOSFETs, and another may be formed as a P-type MOSFET.

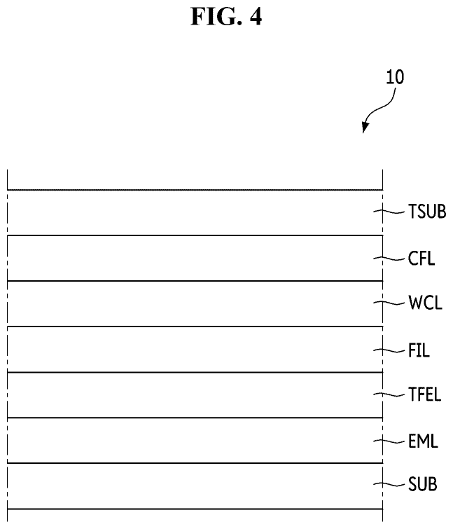

FIG. 4 is a schematic cross-sectional view of the display device 10 according to the embodiment.

Referring to FIG. 4, the display device 10 according to the embodiment may include a substrate SUB, a light emitting element layer EML, a thin-film encapsulation layer TFEL, a filling layer FIL, a wavelength conversion layer WCL, a color filter layer CFL, and a counter substrate TSUB.

The substrate SUB may be an insulating substrate. The substrate SUB may include a transparent material. For example, the substrate SUB may include a transparent insulating material such as glass or quartz. The substrate SUB may be a rigid substrate. However, the disclosure is not limited thereto, and the substrate SUB may also include plastic such as polyimide or may have flexible characteristics so that it can be curved, bent, folded, or rolled.

The light emitting element layer EML may be disposed on the substrate SUB. The light emitting element layer EML may include multiple switching elements and multiple light emitting elements ED located in each subpixel. The switching elements may drive the light emitting elements ED so that the light emitting elements ED can emit light.

The thin-film encapsulation layer TFEL may be disposed on the light emitting element layer EML. The thin-film encapsulation layer TFEL may include an organic layer disposed between multiple inorganic layers to protect the light emitting element layer EML from external moisture and oxygen.

The filling layer FIL may be disposed on the thin-film encapsulation layer TFEL. The filling layer FIL may fill a space between the substrate SUB and the counter substrate TSUB and improve light efficiency by reflecting (or totally reflecting) light emitted from the wavelength conversion layer WCL at an interface with the wavelength conversion layer WCL.

The wavelength conversion layer WCL may be disposed on the filling layer FIL. The wavelength conversion layer WCL may convert the wavelength of light emitted from the light emitting element layer EML to output red light, green light, and blue light.

The color filter layer CFL may be disposed on the wavelength conversion layer WCL. The color filter layer CFL may filter light incident from the outside to reduce reflection of the external light and may improve the color characteristics of light emitted through the wavelength conversion layer WCL.

The counter substrate TSUB may be disposed on the color filter layer CFL. The counter substrate TSUB may encapsulate the light emitting element layer EML together with the substrate SUB. The counter substrate TSUB may include a transparent material. For example, the counter substrate TSUB may include a transparent insulating material such as glass or quartz.

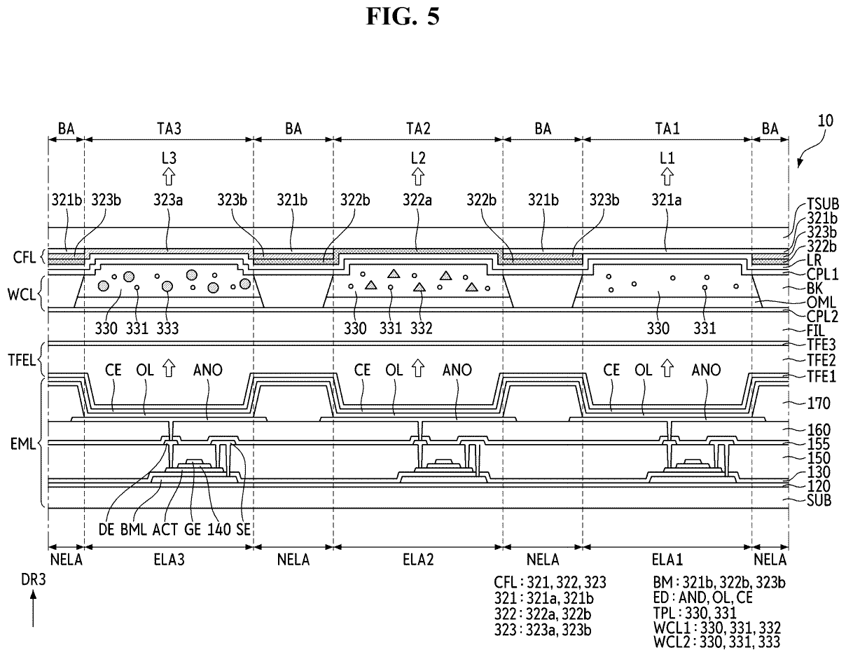

FIG. 5 is a schematic cross-sectional view of the display device 10 according to the embodiment.

Referring to FIG. 5 in conjunction with FIG. 4, the light emitting element layer EML may be disposed on the substrate SUB. The light emitting element layer EML may include a buffer layer 120, bottom metal layers BML, a first insulating layer 130, semiconductor layers ACT, gate electrodes GE, gate insulating layers 140, a second insulating layer 150, source electrodes SE, drain electrodes DE, a third insulating layer 155, a fourth insulating layer 160, light emitting elements ED, and a pixel defining layer 170.

The buffer layer 120 may be disposed on the substrate SUB. The buffer layer 120 may serve to block foreign substances or moisture introduced through the substrate SUB from entering elements disposed on the buffer layer 120. The buffer layer 120 may include an inorganic material such as SiO₂, SiNₓ or SiON and may be formed as a single layer or a multilayer, but the disclosure is not limited thereto.

The bottom metal layers BML may be disposed on the buffer layer 120. The bottom metal layers BML may block external light or light emitted from the light emitting elements to be described later from entering the semiconductor layers ACT. Accordingly, it is possible to prevent leakage current from being generated by light in thin-film transistors which will be described later or reduce the generation of the leakage current.

The bottom metal layers BML may be made of a material that blocks light and has conductivity. In some embodiments, the bottom metal layers BML may include a single material selected from metals such as silver (Ag), nickel (Ni), gold (Au), platinum (Pt), aluminum (Al), copper (Cu), molybdenum (Mo), titanium (Ti) and neodymium (Nd) or may include an alloy of the metals. In some embodiments, the bottom metal layers BML may have a single-layer structure or a multilayer structure. For example, when the bottom metal layers BML have a multilayer structure, each of the bottom metal layers BML may be, but is not limited to, a stacked structure of titanium (Ti)/copper (Cu)/indium tin oxide (ITO) or a stacked structure of titanium (Ti)/copper (Cu)/aluminum oxide (Al₂O₃).

In some embodiments, the bottom metal layers BML may correspond to the semiconductor layers ACT and overlap the semiconductor layers ACT, respectively in the third direction DR3. In some embodiments, the bottom metal layers BML may be wider than the semiconductor layers ACT.

In some embodiments, the bottom metal layers BML may be portion of data lines, power lines, and lines that electrically connect thin-film transistors not illustrated in the drawing to the thin-film transistors (GE, ACT, DE and SE in FIG. 5) illustrated in the drawing. In some embodiments, the bottom metal layers BML may be made of a material having a smaller resistance than the source electrodes SE and the drain electrodes DE.

The first insulating layer 130 may be disposed on the bottom metal layers BML. The first insulating layer 130 may electrically insulate the bottom metal layers BML from the semiconductor layers ACT. The first insulating layer 130 may cover the bottom metal layers BML.

The first insulating layer 130 may include, but is not limited to, an inorganic material such as SiO₂, SiNₓ, SiON, Al₂O₃, TiO₂, Ta₂O, HfO₂, or ZrO₂.

The semiconductor layers ACT may be disposed on the first insulating layer 130. The semiconductor layers ACT may respectively correspond to a first light emitting area ELA1, a second light emitting area ELA2, and a third light emitting area ELA3 in the display area DPA. The semiconductor layers ACT may overlap the bottom metal layers BML, respectively in the third direction DR3. Accordingly, generation of photocurrent in the semiconductor layers ACT can be suppressed.

The semiconductor layers ACT may include an oxide semiconductor. In some embodiments, each of the semiconductor layers ACT may be made of a Zn oxide-based material such as Zn oxide, In—Zn oxide or Ga—In—Zn oxide or may be an In—Ga—Zn—O (IGZO) semiconductor containing metals such as indium (In) and gallium (Ga) in ZnO. However, the disclosure is not limited thereto. For example, the semiconductor layers ACT may also include amorphous silicon or polysilicon.

The gate electrodes GE may be disposed on the semiconductor layers ACT. The gate electrodes GE may overlap the semiconductor layers ACT in the display area DPA. In some embodiments, the gate electrodes GE may be narrower than the semiconductor layers ACT, but the disclosure is not limited thereto.

In consideration of adhesion to an adjacent layer, surface flatness of a layer on which it is stacked, and workability, each of the gate electrodes GE may include one or more of aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W) and copper (Cu) and may be formed as a single layer or a multilayer, but the disclosure is not limited thereto.

The gate insulating layers 140 may be disposed between the semiconductor layers ACT and the gate electrodes GE. The gate insulating layers 140 may insulate the semiconductor layers ACT from the gate electrodes GE. In some embodiments, the gate insulating layers 140 may have a partially patterned shape instead of being formed as one layer on a surface of the substrate SUB (i.e., a first substrate) on one side in a third direction DR3. The gate insulating layers 140 may be narrower than the semiconductor layers ACT and may be wider than the gate electrodes GE, but the disclosure is not limited thereto.

The gate insulating layers 140 may include an inorganic material. For example, the gate insulating layers 140 may include an inorganic material exemplified in the description of the first insulating layer 130.

The second insulating layer 150 may be disposed on the gate insulating layers 140 to cover the semiconductor layers ACT and the gate electrodes GE. In some embodiments, the second insulating layer 150 may function as a planarization layer that provides a flat surface.

The second insulating layer 150 may include an organic material. In some embodiments, the second insulating layer 150 may include, but is not limited to, at least any one of photo acryl (PAC), polystyrene, polymethyl methacrylate (PMMA), polyacrylonitrile (PAN), polyamide, polyimide, polyarylether, heterocyclic polymer, parylene, fluorine-based polymer, epoxy resin, benzocyclobutene series resin, siloxane series resin, and silane resin.

In some embodiments, the second insulating layer 150 may include an inorganic material. For example, the second insulating layer 150 may include an inorganic material exemplified in the description of the first insulating layer 130.

The source electrodes SE and the drain electrodes DE may be spaced apart from each other on the second insulating layer 150. The source electrodes SE and the drain electrodes DE may be electrically connected to the semiconductor layers ACT respectively through contact holes penetrating the second insulating layer 150. The source electrodes SE may penetrate not only the second insulating layer 150 but also the first insulating layer 130 and thus may be electrically connected to the bottom metal layers BML. When the bottom metal layers BML are portion of lines that transmit signals or voltages, the source electrodes SE may be electrically connected and electrically coupled to the bottom metal layers BML to receive voltages provided to the lines. In another embodiment, when the bottom metal layers BML are floating patterns rather than lines, voltages provided to the source electrodes SE may be transmitted to the bottom metal layers BML.

Each of the source electrodes SE and the drain electrodes DE may include aluminum (Al), copper (Cu), titanium (Ti), or the like and may be formed as a multilayer or a single layer. In some embodiments, the source electrodes SE and the drain electrodes DE may have, but are not limited to, a multilayer structure of Ti/Al/Ti.

The semiconductor layers ACT, the gate electrodes GE, the source electrodes SE, and the drain electrodes DE described above may form thin-film transistors which are switching elements. In some embodiments, the thin-film transistors may be located in the first light emitting area ELA1, the second light emitting area ELA2, and the third light emitting area ELA3, respectively. In some embodiments, a portion of each of the thin-film transistors may be located in a non-light emitting area NELA.

The third insulating layer 155 may be disposed on the second insulating layer 150 to cover the thin-film transistors. In some embodiments, the third insulating layer 155 may be a passivation layer.

In some embodiments, the third insulating layer 155 may include an inorganic material. For example, the third insulating layer 155 may include an inorganic material exemplified in the description of the first insulating layer 130.

The fourth insulating layer 160 may be disposed on the third insulating layer 155 to cover the third insulating layer 155. In some embodiments, the fourth insulating layer 160 may be a planarization layer.

The fourth insulating layer 160 may be made of an organic material. In some embodiments, the fourth insulating layer 160 may include acrylic resin, epoxy resin, imide resin or ester resin or may include a photosensitive organic material, but the disclosure is not limited thereto.

Anodes ANO may be disposed on the fourth insulating layer 160 in the display area DPA.

The anodes ANO may overlap the first light emitting area ELA1, the second light emitting area ELA2 and the third light emitting area ELA3, respectively in the third direction DR3, and at least a portion of each of the anodes ANO may extend to the non-light emitting area NELA. The anodes ANO may be electrically connected to the drain electrodes DE of the thin-film transistors.

In some embodiments, the anodes ANO may be reflective electrodes. For example, each of the anodes ANO may be a metal layer including a metal such as Ag, Mg, Al, Pt, Pd, Au, Ni, Nd, Ir or Cr. In an embodiment, each of the anodes ANO may further include a metal oxide layer stacked on the metal layer. The anodes ANO may have a multilayer structure, for example, a two-layer structure of ITO/Ag, Ag/ITO, ITO/Mg or ITO/MgF or a three-layer structure of ITO/Ag/ITO.

The pixel defining layer 170 may be disposed on the anodes ANO. The pixel defining layer 170 may define the first light emitting area ELA1, the second light emitting area ELA2, and the third light emitting area ELA3 as openings that expose the anodes ANO.

The pixel defining layer 170 may overlap a light blocking area BA of the color filter layer CFL, which will be described later, in the third direction DR3. The pixel defining layer 170 may overlap a bank BK, which will be described later, in the third direction DR3.

The pixel defining layer 170 may include, but is not limited to, an organic insulating material such as polyacrylates resin, epoxy resin, phenolic resin, polyamides resin, polyimides resin, unsaturated polyesters resin, polyphenylenethers resin, polyphenylenesulfides resin, or benzocyclobutene (BCB).

A light emitting layer OL may be disposed on the anodes ANO. In some embodiments, the light emitting layer OL may be in the shape of a continuous layer formed over multiple light emitting areas and the non-light emitting area NELA. In some embodiments, the light emitting layer OL may be disposed only in the display area DPA. However, the disclosure is not limited thereto. For example, a portion of the light emitting layer OL may be further located in the non-display area NDA.

In some embodiments, the light emitting layer OL may include an organic layer including an organic material. The organic layer may include an organic light emitting layer, and in some cases, may further include a hole injection/transport layer and/or an electron injection/transport layer as an auxiliary layer that assists light emission. In some embodiments, the light emitting layer OL may have a tandem structure. The tandem structure may include multiple organic light emitting layers stacked in a thickness direction and a charge generation layer disposed between the organic light emitting layers. The tandem structure may include multiple blue organic light emitting layers and green organic light emitting layers stacked in the thickness direction. However, the disclosure is not limited thereto.

In some embodiments, in case that the display device 10 is a micro-light emitting diode display device, a nano-light emitting diode display device, or the like, the light emitting layer OL may include an inorganic material such as an inorganic semiconductor.

A cathode CE may be disposed on the light emitting layer OL. In some embodiments, the cathode CE may be disposed on the light emitting layer OL and may be in the shape of a continuous layer formed over the light emitting areas ELA1 through ELA3 and the non-light emitting area NELA. For example, the cathode CE may cover (or completely cover) the light emitting layer OL.

The cathode CE may have translucency or transparency. In case that a thickness of the cathode CE is tens to hundreds of angstroms (Å), the cathode CE may have translucency. In some embodiments, in case that the cathode CE has translucency, it may include Ag, Mg, Cu, Al, Pt, Pd, Au, Ni, Nd, Ir, Cr, Li, Ca, LiF/Ca, LiF/Al, Mo, Ti, or a compound or mixture thereof, e.g., a mixture of Ag and Mg. The cathode CE may also have transparency by including a transparent conductive oxide. In some embodiments, in case that the cathode CE has transparency, it may include tungsten oxide (WₓOₓ), titanium oxide (TiO₂), indium tin oxide (ITO), indium zinc oxide (IZO), zinc oxide (ZnO), indium tin zinc oxide (ITZO), or magnesium oxide (MgO).

The anodes ANO, the light emitting layer OL, and the cathode CE may form the light emitting elements ED. For example, the anode ANO, the light emitting layer OL and the cathode CE overlapping the first light emitting area ELA1 may form a first light emitting element, the anode ANO, the light emitting layer OL and the cathode CE overlapping the second light emitting area ELA2 may form a second light emitting element, and the anode ANO, the light emitting layer OL and the cathode CE overlapping the third light emitting area ELA3 may form a third light emitting element. Each of the first light emitting element, the second light emitting element, and the third light emitting element may emit output light. The output light emitted from each light emitting element ED may have a peak wavelength of 440 to 480 nm. For example, the output light LE may be blue light. In some embodiments, the output light LE may further include green light in addition to blue light.

The thin-film encapsulation layer TFEL may be disposed on the light emitting element layer EML. The thin-film encapsulation layer TFEL may be disposed on the cathode CE. The thin-film encapsulation layer TFEL may protect elements located under the thin-film encapsulation layer TFEL from external foreign substances such as moisture. The thin-film encapsulation layer TFEL is commonly located in the first light emitting area ELA1, the second light emitting area ELA2, the third light emitting area ELA3, and the non-light emitting area NELA.

The thin-film encapsulation layer TFEL may include a first encapsulation layer TFE1, a second encapsulation layer TFE2, and a third encapsulation layer TFE3 sequentially stacked on the cathode CE.

The first encapsulation layer TFE1 may cover (or completely cover) the cathode CE in the display area DPA to cover the first light emitting element, the second light emitting element and the third light emitting element. The second encapsulation layer TFE2 may be disposed on the first encapsulation layer TFE1 to cover the first light emitting element, the second light emitting element and the third light emitting element. The third encapsulation layer TFE3 may be disposed on the second encapsulation layer TFE2 to cover (or completely cover) the second encapsulation layer TFE2.

In some embodiments, each of the first encapsulation layer TFE1 and the third encapsulation layer TFE3 may include an inorganic material, for example, may be made of, but not limited to, silicon nitride, aluminum nitride, zirconium nitride, titanium nitride, hafnium nitride, tantalum nitride, silicon oxide, aluminum oxide, titanium oxide, tin oxide, cerium oxide, silicon oxynitride (SiON), or lithium fluoride.

In some embodiments, the second encapsulation layer TFE2 may include an organic material, for example, may be made of, but not limited to, acrylic resin, methacrylic resin, polyisoprene, vinyl resin, epoxy resin, urethane resin, cellulose resin, or perylene resin.

The counter substrate TSUB may be disposed on the substrate SUB on which the light emitting element layer EML and the thin-film encapsulation layer TFEL are located. The color filter layer CFL, a low refractive layer LR, a first capping layer CPL1, and the wavelength conversion layer WCL may be sequentially disposed on a surface of the counter substrate TSUB.

The color filter layer CFL may be disposed on another side of the counter substrate TSUB in the third direction DR3, for example, between the counter substrate TSUB and the substrate SUB. The color filter layer CFL may include filtering pattern areas and a light-blocking pattern portion BM. The light-blocking pattern portion BM may surround the filtering pattern areas. The filtering patterns of the color filter layer CFL may define light transmitting areas, and the light-blocking pattern portion BM may define the light blocking area BA.

The color filter layer CFL may include a first color filter 321, a second color filter 322, and a third color filter 323 as illustrated in FIG. 5. The first color filter 321 may absorb all of second light and third light except for first light, the second color filter 322 may absorb all of the first light and the third light except for the second light, and the third color filter 323 may absorb all of the first light and the second light except for the third light. For example, the first color filter 321 may transmit the first light, the second color filter 322 may transmit the second light, and the third color filter 323 may transmit the third light.

In some embodiments, the first color filter 321 may be a blue color filter and may include a blue colorant. As used herein, the term “colorant” is a concept encompassing both a dye and a pigment. The first color filter 321 may include a base resin, and the blue colorant may be dispersed within the base resin. In some embodiments, the second color filter 322 may be a green color filter and may include a green colorant. The second color filter 322 may include a base resin, and the green colorant may be dispersed within the base resin. In some embodiments, the third color filter 323 may be a red color filter and may include a red colorant. The third color filter 323 may include a base resin, and the red colorant may be dispersed within the base resin.

The first color filter 321 may include a first filtering pattern area 321a and a first light-blocking pattern area 321b surrounding the first filtering pattern area 321a. The second color filter 322 may include a second filtering pattern area 322a and a second light-blocking pattern area 322b surrounding the second filtering pattern area 322a. The third color filter 323 may include a third filtering pattern area 323a and a third light-blocking pattern area 323b surrounding the third filtering pattern area 323a.

For example, the first filtering pattern area 321a of the first color filter 321 overlaps a first light transmitting area TA1. The first light-blocking pattern area 321b of the first color filter 321 surrounds the first filtering pattern area 321a overlapping the first light transmitting area TA1, but may not overlap a second light transmitting area TA2 and a third light transmitting area TA3 and may overlap the light blocking area BA. The second filtering pattern area 322a of the second color filter 322 overlaps the second light transmitting area TA2. The second light-blocking pattern area 322b of the second color filter 322 surrounds the second filtering pattern area 322a overlapping the second light transmitting area TA2, but may not overlap the first light transmitting area TA1 and the third light transmitting area TA3 and may overlap the light blocking area BA. The third filtering pattern area 323a of the third color filter 323 overlaps the third light transmitting area TA3. The third light-blocking pattern area 323b of the third color filter 323 surrounds the third filtering pattern area 323a overlapping the third light transmitting area TA3, but may not overlap the first light transmitting area TA1 and the second light transmitting area TA2 and may overlap the light blocking area BA. For example, the filtering pattern areas of the color filter layer CFL may include the first filtering pattern area 321a of the first color filter 321, the second filtering pattern area 322a of the second color filter 322, and the third filtering pattern area 323a of the third color filter 323, and the light-blocking pattern portion BM may have a structure in which the first light-blocking pattern area 321b of the first color filter 321, the second light-blocking pattern area 322b of the second color filter 322, and the third light-blocking pattern area 323b of the third color filter 323 are stacked.

The first filtering pattern area 321a of the first color filter 321 may function as a blocking filter that blocks red light and green light. For example, the first filtering pattern area 321a may selectively transmit the first light (e.g., blue light) and block or absorb the second light (e.g., green light) and the third light (e.g., red light).

The second filtering pattern area 322a of the second color filter 322 may function as a blocking filter that blocks blue light and red light. For example, the second filtering pattern area 322a may selectively transmit the second light (e.g., green light) and block or absorb the first light (e.g., blue light) and the third light (e.g., red light).

The third filtering pattern area 323a of the third color filter 323 may function as a blocking filter that blocks blue light and green light. For example, the third filtering pattern area 323a may selectively transmit the third light (e.g., red light) and block or absorb the first light (e.g., blue light) and the second light (e.g., green light).

In some embodiments, the light-blocking pattern portion BM may have a structure in which the first light-blocking pattern area 321b, the third light-blocking pattern area 323b, and the second light-blocking pattern area 322b are sequentially stacked from the surface of the counter substrate TSUB. However, the disclosure is not limited thereto. In some embodiments, the light-blocking pattern portion BM may have a structure in which the first light-blocking pattern area 321b, the second light-blocking pattern area 322b, and the third light-blocking pattern area 323b are sequentially stacked from the surface of the counter substrate TSUB. In another embodiment, the light-blocking pattern portion BM may not be composed of the color filters 321, 322 and 323 described above, but may be formed as a separate organic light blocking material, for example, may be formed by coating and exposing an organic light blocking material. For ease of description, a case where the light-blocking pattern portion BM has a structure in which the first light-blocking pattern area 321b, the third light-blocking pattern area 323b, and the second light-blocking pattern area 322b are sequentially stacked in the third direction DR3 will be mainly described. The light-blocking pattern portion BM configured as described above may absorb all of the first light, the second light, and the third light.

The low refractive layer LR may be disposed on a surface of the color filter layer CFL, for example, on another side in the third direction DR3. The low refractive layer LR has a lower refractive index than a first light transmitting member TPL, a second light transmitting member WCL1, and a third light transmitting member WCL2 which will be described later. Therefore, the low refractive layer LR may induce total reflection of light traveling from the first light transmitting member TPL, the second light transmitting member WCL1, and the third light transmitting member WCL2 to the low refractive layer LR, thereby reusing the light.

The low refractive layer LR may include an organic material or an inorganic material. In some embodiments, the refractive index of the low refractive layer LR may be 1.3 or less. In case that the refractive index of the low refractive layer LR is about 1.3 or less, a difference in refractive index between the first light transmitting member TPL, the second light transmitting member WCL1, and the third light transmitting member WCL2 is large enough to cause total reflection of light.

The first capping layer CPL1 may be disposed on a surface of the low refractive layer LR to cover the low refractive layer LR. The first capping layer CPL1 may prevent damage to or contamination of the low refractive layer LR and the color filter layer CFL by preventing penetration of impurities such as moisture or air from the outside into the low refractive layer LR or the color filter layer CFL.

The first capping layer CPL1 may include an inorganic material. In some embodiments, the first capping layer CPL1 may include an inorganic material such as SiO₂, SiNₓ or SiON and may be formed as a single layer or a multilayer, but the disclosure is not limited thereto.

The wavelength conversion layer WCL may be disposed on a surface of the first capping layer CPL1. The wavelength conversion layer WCL may include the bank BK, the first light transmitting member TPL, the second light transmitting member WCL1, the third light transmitting member WCL2, organic layers OML, and a second capping layer CPL2.

The bank BK may be disposed on a surface of the first capping layer CPL1 on another side in the third direction DR3 based on FIG. 5 and may be located in a lattice shape to form spaces for accommodating light transmitting members. For example, the bank BK may serve to define the spaces in which the light transmitting members are located. The bank BK may contact (or directly contact) the surface of the first capping layer CPL1 on another side in the third direction DR3. The bank BK may surround the light transmitting members in a plan view. The bank BK may overlap the non-light emitting area NELA and the light blocking area BA. The bank BK may not overlap the light emitting areas ELA1, ELA2 and ELA3 and the light transmitting areas TA1, TA2 and TA3.

In some embodiments, the bank BK may include, but is not limited to, a photocurable organic material or a photocurable organic material including a light blocking material. In some embodiments, the bank BK may not be hydrophobic and may be, for example, non-hydrophobic.

The first light transmitting member TPL may overlap the first light transmitting area TA1, the second light transmitting member WCL1 may overlap the second light transmitting area TA2, and the third light transmitting member WCL2 may overlap the third light transmitting area TA3. The first light transmitting member TPL, the second light transmitting member WCL1, and the third light transmitting member WCL2 may be referred to as wavelength conversion layers or wavelength conversion material layers.

The first light transmitting member TPL may be located in a space defined by the bank BK and may overlap the first light emitting area ELA1 and the first light transmitting area TA1 in the third direction DR3. The first light transmitting member TPL may contact (or directly contact) the first capping layer CPL1 and the bank BK.

The first light transmitting member TPL may be a light transmitting pattern that transmits incident light. The first light transmitting member TPL may transmit light of a first color emitted from the light emitting element layer EML as it is. For example, output light provided by the first light emitting element may be blue light as described above and may pass through the first light transmitting member TPL and the first filtering pattern area 321a of the first color filter 321 to exit the display device 10. For example, first output light L1 emitted from the first light emitting area ELA1 to the outside through the first light transmitting area TA1 may be blue light.

The first light transmitting member TPL may include a base resin 330 and light scatterers 331.

The base resin 330 may be made of an organic material having high light transmittance. In some embodiments, the base resin 330 may include, but is not limited to, an organic material such as epoxy resin, acrylic resin, cardo resin, or imide resin.

The light scatterers 331 may have a different refractive index from the base resin 330 and may form an optical interface with the base resin 330. The light scatterers 331 may be light scattering particles. The light scatterers 331 may scatter incident light in random directions regardless of the incident direction of the incident light without substantially converting the wavelength of the incident light passing through the light transmitting area TA1.

The light scatterers 331 may be materials that scatter at least a portion of transmitted light and may include metal oxide particles or organic particles. In some embodiments, the light scatterers 331 may include titanium oxide (TiO₂), zirconium oxide (ZrO₂), aluminum oxide (Al₂O₃), indium oxide (In₂O₃), zinc oxide (ZnO) or tin oxide (SnO₂) as the metal oxide and may include acrylic resin or urethane resin as the organic particles, but the disclosure is not limited thereto.

The second light transmitting member WCL1 may be located in a space defined by the bank BK and may overlap the second light emitting area ELA2 and the second light transmitting area TA2 in the third direction DR3. The second light transmitting member WCL1 may contact (or directly contact) the first capping layer CPL1 and the bank BK.

The second light transmitting member WCL1 may be a wavelength converting pattern that converts or shifts a peak wavelength of incident light into another specific peak wavelength and outputs light having the specific peak wavelength. The second light transmitting member WCL1 may convert light of the first color emitted from the light emitting element layer EML into light of a second color and output the light of the second color. For example, output light provided by the second light emitting element may be blue light as described above and may be converted into green light having a peak wavelength in the range of about 510 to about 550 nm as it passes through the second light transmitting member WCL1 and the second filtering pattern area 322a of the second color filter 322. Accordingly, the green light may be emitted to the outside of the display device 10. For example, second output light L2 emitted from the second light emitting area ELA2 to the outside through the second light transmitting area TA2 may be green light.

The second light transmitting member WCL1 may include a base resin 330, light scatterers 331 dispersed in the base resin 330, and first wavelength shifters 332 dispersed in the base resin 330.

The first wavelength shifters 332 may convert or shift a peak wavelength of incident light into another specific peak wavelength. The first wavelength shifters 332 may convert the output light, which is blue light provided by the second light emitting element, into green light having a single peak wavelength in the range of about 510 to about 550 nm and output the green light.

In some embodiments, the first wavelength shifters 332 may be, but are not limited to, quantum dots, quantum rods, or phosphors. For ease of description, a case where the first wavelength shifters 332 are quantum dots will be mainly described below. The quantum dots may be particulate materials that emit light of a specific color in case that electrons transit from a conduction band to a valence band. The quantum dots may be semiconductor nanocrystalline materials. The quantum dots may have a specific band gap according to their composition and size. Thus, the quantum dots may absorb light and then emit light having a unique wavelength.

The quantum dots may include a group III-VI semiconductor compound; a group II-VI semiconductor compound; a group III-V semiconductor compound; a group III-VI semiconductor compound; a group I-III-VI semiconductor compound; a group IV-VI semiconductor compound; a group IV element or compound; or any combination thereof.

Examples of the group II-VI semiconductor compound include a binary compound such as CdS, CdSe, CdTe, ZnS, ZnSe, ZnTe, ZnO, HgS, HgSe, HgTe, MgSe or MgS; a ternary compound such as CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe or MgZnS; a quaternary compound such as CdZnSeS, CdZnSeTe, CdZnSTe, CdHgSeS, CdHgSeTe, CdHgSTe, HgZnSeS, HgZnSeTe or HgZnSTe; and any combination thereof.

Examples of the group III-V semiconductor compound may include a binary compound such as GaN, GaP, GaAs, GaSb, AlN, AlP, AlAs, AlSb, InN, InP, InAs or InSb; a ternary compound such as GaNP, GaNAs, GaNSb, GaPAs, GaPSb, AlNP, AlNAs, AlNSb, AlPAs, AlPSb, InGaP, InNP, InAlP, InNAs, InNSb, InPAs, InPSb or GaAlNP; a quaternary compound such as GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs or InAlPSb; and any combination thereof. The group III-V semiconductor compound may further include a group II element. Examples of the group III-V semiconductor compound further including the group II element may include InZnP, InGaZnP, and InAlZnP.

Examples of the group III-VI semiconductor compound may include a binary compound such as GaS, Ga₂S₃, GaSe, Ga₂Se₃, GaTe, InS, InSe, In₂Se₃ or InTe; a ternary compound such as InGaS₃ or InGaSe₃; and any combination thereof.

Examples of the group I-III-VI semiconductor compound may include a ternary compound such as AgInS, AgInS₂, AgInSe₂, AgGaS, AgGaS₂, AgGaSe₂, CuInS, CuInS₂, CuInSe₂, CuGaS₂, CuGaSe₂, CuGaO₂, AgGaO₂ or AgAlO₂; a quaternary compound such as AgInGaS₂ or AgInGaSe₂; and any combination thereof.

Examples of the group IV-VI semiconductor compound may include a binary compound such as SnS, SnSe, SnTe, PbS, PbSe or PbTe; a ternary compound such as SnSeS, SnSeTe, SnSTe, PbSeS, PbSeTe, PbSTe, SnPbS, SnPbSe or SnPbTe; a quaternary compound such as SnPbSSe, SnPbSeTe or SnPbSTe; and any combination thereof.

The group IV element or compound may include a unary compound such as Si or Ge; a binary compound such as SiC or SiGe; or any combination thereof.

Each element included in a multi-element compound such as a binary, ternary, or quaternary compound may be present in particles at a uniform or non-uniform concentration. For example, each of the above chemical formulas represents the types of elements included in a compound, and an element ratio of the compound may vary. For example, AgInGaS₂ may indicate AgInₓGa₁₋ₓS₂ (where x is a real number between 0 and 1).

The quantum dots may have a single structure or a core-shell dual structure in which the concentration of each element included in the quantum dots is uniform. For example, a material included in the core and a material included in the shell may be different from each other.

The shell of each quantum dot may serve as a protective layer for maintaining semiconductor characteristics by preventing chemical denaturation of the core and/or as a charging layer for giving electrophoretic characteristics to the quantum dot. The shell may be a single layer or a multilayer. An interface between the core and the shell may have a concentration gradient in which the concentration of an element present in the shell is reduced toward the center.

The shell of each quantum dot may be, for example, a metal or non-metal oxide, a semiconductor compound, or a combination thereof. Examples of the metal or non-metal oxide may include a binary compound such as SiO₂, Al₂O₃, TiO₂, ZnO, MnO, Mn₂O₃, Mn₃O₄, CuO, FeO, Fe₂O₃, Fe₃O₄, CoO, Co₃O₄ or NiO; a ternary compound such as MgAl₂O₄, CoFe₂O₄, NiFe₂O₄ or CoMn₂O₄; and any combination thereof. Examples of the semiconductor compound may include a group III-VI semiconductor compound, a group II-VI semiconductor compound, a group III-V semiconductor compound, a group III-VI semiconductor compound, a group I-III-VI semiconductor compound, a group IV-VI semiconductor compound, and any combination thereof as described herein. For example, the semiconductor compound may include CdS, CdSe, CdTe, ZnS, ZnSe, ZnTe, ZnSeS, ZnTeS, GaAs, GaP, GaS, GaSe, AgGaS, AgGaS₂, GaSb, HgS, HgSe, HgTe, InAs, InP, InGaP, InSb, AlAs, AlP, AlSb, or any combination thereof.

Each element included in a multi-element compound such as a binary compound or a ternary compound may be present in particles at a uniform or non-uniform concentration. For example, each of the above chemical formulas may represent the types of elements included in a compound, and an element ratio of the compound may vary.

The quantum dots may have a full width of half maximum (FWHM) of an emission wavelength spectrum of about 45 nm or less, for example, about 40 nm or less, more for example, about 30 nm or less. In this range, color purity or color reproducibility can be improved. Since light emitted through the quantum dots is radiated in all directions, a viewing angle of the light can be improved.

The quantum dots may be in the form of spherical, pyramidal, multi-arm or cubic nanoparticles, nanotubes, nanowires, nanofibers, nanoplate particles, etc.

Since an energy band gap can be controlled by adjusting the size of the quantum dots or the element ratio of a quantum dot compound, light of various wavelength bands can be obtained from a quantum dot light emitting layer. Therefore, it is possible to implement a light emitting element that emits light of various wavelengths using the above-described quantum dots (quantum dots having different sizes or different element ratios of the quantum dot compound). For example, the size of the quantum dots or the element ratio of the quantum dot compound may be adjusted so that red, green, and/or blue light is emitted. The quantum dots may emit white light by combining light of various colors.

A portion of the output light provided by the second light emitting element may be transmitted through the second light transmitting member WCL1 without being converted into green light by the first wavelength shifters 332. Of the output light, a component incident on the second filtering pattern area 322a of the second color filter 322 without being wavelength-converted by the second light transmitting member WCL1 may be blocked by the second filtering pattern area 322a. On the other hand, green light into which the output light has been converted by the second light transmitting member WCL1 is transmitted through the second filtering pattern area 322a and then emitted to the outside. For example, the second output light L2 emitted to the outside of the display device 10 through the second light transmitting area TA2 may be green light.

The third light transmitting member WCL2 may be located in a space defined by the bank BK and may overlap the third light emitting area ELA3 and the third light transmitting area TA3 in the third direction DR3. The third light transmitting member WCL2 may contact (or directly contact) the first capping layer CPL1 and the bank BK.

The third light transmitting member WCL2 may be a wavelength converting pattern that converts or shifts a peak wavelength of incident light into another specific peak wavelength and outputs light having the specific peak wavelength. For example, output light provided by the third light emitting element may be blue light as described above and may be converted into red light having a peak wavelength in the range of about 610 to about 650 nm as it passes through the third light transmitting member WCL2 and the third filtering pattern area 323a of the third color filter 323. Accordingly, the red light may be emitted to the outside of the display device 10. For example, third output light L3 emitted from the third light emitting area ELA3 to the outside through the third light transmitting area TA3 may be red light.

The third light transmitting member WCL2 may include a base resin 330, light scatterers 331 dispersed in the base resin 330, and second wavelength shifters 333 dispersed in the base resin 330.

The second wavelength shifters 333 may convert or shift a peak wavelength of incident light into another specific peak wavelength. The second wavelength shifters 333 may convert the output light, which is blue light provided by the third light emitting element, into red light having a single peak wavelength in the range of about 610 to about 650 nm and output the red light. In some embodiments, the second wavelength shifters 333 may be, but are not limited to, quantum dots, quantum rods, or phosphors. In case that the second wavelength shifters 333 are quantum dots, they may have substantially the same composition as the above-described first wavelength shifters 332 in case that the first wavelength shifters 332 are quantum dots. Therefore, a description of the second wavelength shifters 333 will be omitted.

A portion of the output light provided by the third light emitting element may be transmitted through the third light transmitting member WCL2 without being converted into red light by the second wavelength shifters 333. Of the output light, a component incident on the third filtering pattern area 323a of the third color filter 323 without being wavelength-converted by the third light transmitting member WCL2 may be blocked by the third filtering pattern area 323a. On the other hand, red light into which the output light has been converted by the third light transmitting member WCL2 is transmitted through the third filtering pattern area 323a and then emitted to the outside. For example, the third output light L3 emitted to the outside of the display device 10 through the third light transmitting area TA3 may be red light.

The organic layers OML may be spaced apart from each other between the bank BK interposed between the organic layers OML. The organic layers OML may be located in the light transmitting areas separated by the bank BK. For example, the organic layers OML may overlap the first light transmitting area TA1, the second light transmitting area TA2, and the third light transmitting area TA3. The organic layers OML may be located in a patterned shape and may be disposed (or directly disposed) on the light transmitting members TPL, WCL1 and WCL2, respectively in the third direction DR3. For example, the organic layers OML may contact surfaces of the first light transmitting member TPL, the second light transmitting member WCL1, and the third light transmitting member WCL2. Accordingly, the organic layers OML may protect the light transmitting members TPL, WCL1 and WCL2 from being etched during a manufacturing process which will be described later. The organic layers OML may be spaced apart from a lower surface of the bank BK and may not cover (or overlap) the bank BK. For example, surfaces of the organic layers OML, for example, lower surfaces of the organic layers OML may be aligned (or coplanar) with the lower surface of the bank BK. As used herein, the term “align” may mean lying on the same plane (coplanar). For example, surfaces of the organic layers OML which contact the second capping layer CPL2 may be disposed on the same plane (or the same layer) as a surface of the bank BK which contacts the second capping layer CPL2.

The organic layers OML may include a transparent organic material that can transmit light. For example, the organic layers OML may be made of, but not limited to, acrylic resin, methacrylic resin, polyisoprene, vinyl resin, epoxy resin, urethane resin, cellulose resin, or perylene resin.

In some embodiments, a refractive index of the organic layers OML may be 1.7 or less. Since the refractive index of each light transmitting member TPL, WCL1 or WCL2 is about 1.7 to about 1.8, the organic layers OML may be formed to have a lower refractive index than the light transmitting members TPL, WCL1 and WCL2 to reduce light loss.

The second capping layer CPL2 may be disposed on the surfaces of the bank BK and the organic layers OML to cover the bank BK and the organic layers OML. The second capping layer CPL2 may prevent damage to or contamination of each light transmitting member TPL, WCL1 or WLC2 and the organic layers OML by preventing penetration of impurities such as moisture or air from the outside into each light transmitting member TPL, WCL1 or WLC2 and the organic layers OML. The second capping layer CPL2 may be formed flat without a step. Since the lower surfaces of the bank BK and the organic layers OML are aligned (or coplanar) with each other as described above, the second capping layer CPL2 formed on the surfaces may be flat. In some embodiments, the second capping layer CPL2 may contact (or directly contact) the lower surface of the bank BK and the lower surfaces of the organic layers OML.

The second capping layer CPL2 may include an inorganic material. In some embodiments, the second capping layer CPL2 may include an inorganic material such as SiO₂, SiNₓ or SiON and may be formed as a single layer or a multilayer, but the disclosure is not limited thereto.

The filling layer FIL may be disposed between the counter substrate TSUB and the substrate SUB. The filling layer FIL may be interposed between the wavelength conversion layer WCL and the thin-film encapsulation layer TFEL to fill a space between the wavelength conversion layer WCL and the thin-film encapsulation layer TFEL. In some embodiments, the filling layer FIL may contact (or directly contact) the third encapsulation layer TFE3 of the thin-film encapsulation layer TFEL and the second capping layer CPL2 of the wavelength conversion layer WCL, but the disclosure is not limited thereto.

In some embodiments, the filling layer FIL may be made of a material whose extinction coefficient is substantially zero. A refractive index and an extinction coefficient may be correlated, and the extinction coefficient may decrease as the refractive index decreases. In case that the refractive index is about 1.7 or less, the extinction coefficient may converge to substantially zero. In some embodiments, the filling layer FIL may be made of a material having a refractive index of about 1.7 or less. Accordingly, light provided by the above self-light emitting elements can be prevented from being absorbed by the filling layer FIL as it passes through the filling layer FIL, or the absorption of the light by the filling layer FIL can be minimized. In some embodiments, the filling layer FIL may be made of an organic material having a refractive index of about 1.4 to about 1.6.

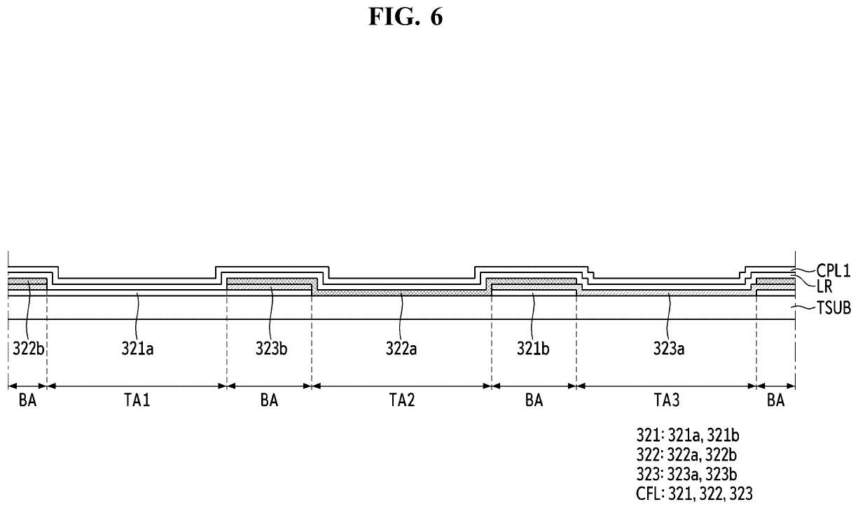

A method of manufacturing a display device according to FIG. 5 described above will now be described with reference to FIGS. 6 through 12.

FIGS. 6 through 12 are schematic cross-sectional views illustrating each process in a method of manufacturing a display device according to an embodiment. The manufacturing method of FIGS. 6 through 12 is a method of manufacturing a display device corresponding to FIG. 5 described above.

The method of manufacturing a display device 10 according to the embodiment may include forming a color filter layer CFL on a counter substrate TSUB, sequentially forming a low refractive layer LR and a first capping layer CPL1 on the color filter layer CFL, forming a bank BK on the first capping layer CPL1, forming a hydrophobic layer HPL on the bank BK, forming each light transmitting member TPL, WCL1 or WCL2 between portions of the bank BK, forming an organic material layer OMLL on the bank BK and each light transmitting member TPL, WCL1 or WCL2, forming organic layers OML by removing the hydrophobic layer HPL and a portion of the organic material layer OMLL, and forming a second capping layer CPL2 on the bank BK and the organic layers OML.

Firstly, referring to FIG. 6, a color filter layer CFL may be formed on a counter substrate TSUB. The color filter layer CFL may be formed using a photo process.

For example, a first color material layer may be applied onto the counter substrate TSUB and patterned using a photo process to form a first color filter 321 including a first filtering pattern area 321a and a first light-blocking pattern area 321b surrounding the first filtering pattern area 321a. Next, a second color material layer may be applied and then patterned using a photo process to form a third color filter 323 including a third filtering pattern area 323a and a third light-blocking pattern area 323b surrounding the third filtering pattern area 323a. A third color material layer may be applied and then patterned using a photo process to form a second color filter 322 including a second filtering pattern area 322a and a second light-blocking pattern area 322b surrounding the second filtering pattern area 322a.

The formation of the color filter layer CFL may result in the division of the counter substrate TSUB into light transmitting areas TA1 through TA3 and a light blocking area BA. For example, a first light transmitting area TA1 overlapping the first filtering pattern area 321a, a second light transmitting area TA2 overlapping the second filtering pattern area 322a, a third light transmitting area TA3 overlapping the third filtering pattern area 323a, and the light blocking area BA overlapping the first light-blocking pattern area 321b, the second light-blocking pattern area 322b or the third light-blocking pattern area 323b may be defined.

Next, a low refractive layer LR may be formed on the color filter layer CFL, and a first capping layer CPL1 may be formed on the low refractive layer LR. If the low refractive layer LR includes an inorganic material, it may be formed through a chemical vapor deposition (CVD) or plasma vapor deposition (PVD) process. If the low refractive layer LR includes an organic material, it may be formed through a solution process such as spin coating or inkjet printing. The first capping layer CPL1 may be formed through a CVD or PVD process.

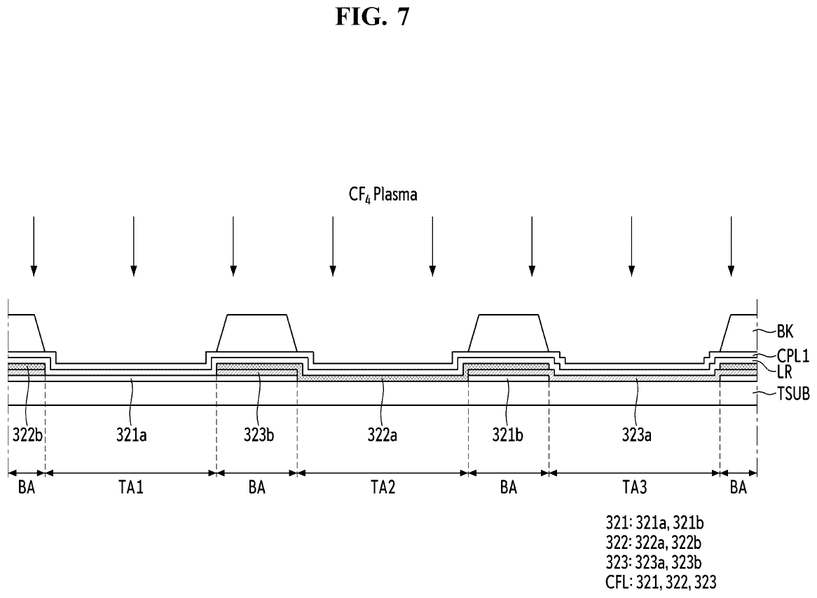

Next, referring to FIG. 7, a bank BK may be formed on the first capping layer CPL1. The bank BK may be formed through a photo process. For example, the bank BK may be formed by applying a bank material layer and then patterning the bank material layer through a photo process. The bank BK may be formed on the first capping layer CPL1 to overlap the light blocking area BA and not overlap each light transmitting area TA1, TA2 or TA3.

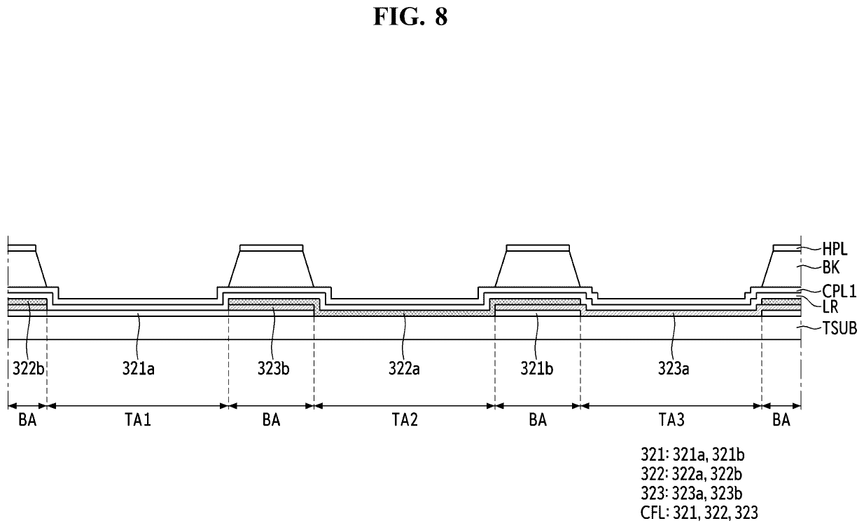

Next, referring to FIGS. 7 and 8, a hydrophobic layer HPL may be formed on the bank BK. For example, an ashing process and a plasma process are performed on the counter substrate TSUB on which the bank BK is formed.

The ashing process may be a process for removing a residual layer that may exist on the bank BK and the first capping layer CPL1 on which the bank BK is formed. The ashing process may be a plasma treatment process using, for example, Ar, N₂, He, O₂, or a mixed gas thereof as a reaction gas. The ashing process may be performed for several seconds to several minutes, but the disclosure is not limited thereto. The ashing process may remove a residual bank layer remaining in an area between portions of the bank BK, for example, on a surface of the first capping layer CPL1 on which light transmitting members to be described later are to be formed. If the ashing process is not performed, the spreadability of light transmitting member materials dropped onto the first capping layer CPL1 may be reduced. Therefore, in the embodiment, the ashing process may be performed to remove the residual bank layer, thereby improving the spreadability of the light transmitting member materials.

The plasma process may be a process for forming the hydrophobic layer HPL on the bank BK. The plasma process may use a CF₄ gas. In case that the plasma process using the CF₄ gas is performed on the bank BK, CF₄ plasma may combine with carbon (C) of the bank BK to form CF₃ chains on a surface of the bank BK. The CF₃ chains formed on the surface of the bank BK may exhibit hydrophobicity by reducing surface energy. In FIG. 8, the CF₃ chains formed on the surface of the bank BK are illustrated and described as the hydrophobic layer HPL. However, in reality, the CF₃ chains may not be observed as a layer.

The plasma process may be performed in a pressure range of about 30 to about 120 mTorr. The plasma process may be performed at a pressure of about 100 mTorr. The plasma process may be performed in a power range of about 400 to 600 W. The plasma process may be performed at a power of about 500 W.

The plasma process may be performed for about 20 to 40 seconds. The plasma process may be performed for about 30 seconds.

In some embodiments, after the bank BK is formed, the ashing process using the O₂ gas may be performed for about 60 seconds to remove a residual layer, and the plasma process using the CF₄ gas may be performed at a pressure of about 100 mTorr and a power of about 500 W for about 30 seconds to form the hydrophobic layer HPL.

If an antistatic process, for example, a process for removing static electricity is performed after the plasma process, the hydrophobicity of the surface of the bank BK may be lost. For example, if an antistatic process using an O₂, Ar, or N₂ gas is performed, the CF₃ chains bonded to the surface of the bank BK may be lost, resulting in a loss of hydrophobicity. Therefore, in the embodiment, the antistatic process using the O₂, Ar, or N₂ gas may be omitted.

In case that a bake process is performed after the plasma process, the hydrophobicity of the surface of the bank BK may be reduced. For example, the CF₃ chains bonded to the surface of the bank BK may be lost by a high-temperature heat treatment process of the bake process, resulting in a loss of hydrophobicity. Therefore, in the embodiment, the bake process may be omitted.

The hydrophobic layer HPL may be formed as a mono layer or a fluorine layer having a thickness range of about 1,000 Å or less. The hydrophobic layer HPL illustrated in FIG. 8 may be formed only on an upper surface of the bank BK. The hydrophobic layer HPL may be formed on the upper surface of the bank BK except for side surfaces of the bank BK by performing the CF₄ plasma process in the above high power range. If the hydrophobic layer HPL is also formed on the side surfaces of the bank BK, a defect in which each light transmitting member TPL, WCL1 or WCL2 to be described later is lifted from the side surfaces of the bank BK may occur.

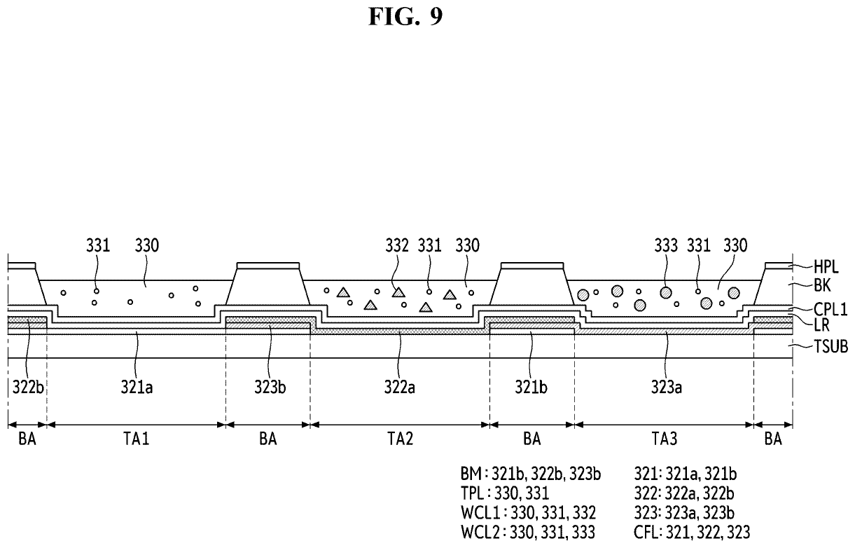

Next, referring to FIG. 9, a first light transmitting member TPL, a second light transmitting member WCL1, or a third light transmitting member WCL2 may be formed in each light transmitting area TA1, TA2 or TA3 formed between portions of the bank BK.

Each of the first light transmitting member TPL, the second light transmitting member WCL1, and the third light transmitting member WCL2 may be formed by an inkjet printing process. The first light transmitting member TPL, the second light transmitting member WCL1, and the third light transmitting member WCL2 may be formed sequentially, but may also be formed regardless of order.

In some embodiments, ink including a first light-transmitting member material, for example, a base resin 330 and light scatterers 331 may be applied onto the first light transmitting area TA1 using an inkjet printing process and then dried to form the first light transmitting member TPL. Ink including a second light-transmitting member material, for example, a base resin 330, light scatterers 331 and first wavelength shifters 332 may be applied onto the second light transmitting area TA2 using an inkjet printing process and then dried to form the second light transmitting member WCL1. Ink including a third light-transmitting member material, for example, a base resin 330, light scatterers 331 and second wavelength shifters 333 may be applied onto the third light transmitting area TA3 using an inkjet printing process and then dried to form the third light transmitting member WCL2.

Since the hydrophobic layer HPL is disposed on the upper surface of the bank BK, in case that each light-transmitting member material is applied to a corresponding light transmitting area, it can be prevented from overflowing from the light transmitting area to other adjacent light transmitting areas beyond the bank BK. For example, in case that the second light-transmitting member material is applied to the second light transmitting area TA2, it can be prevented from overflowing to an adjacent first light transmitting area TA1 or an adjacent third light transmitting area TA3.

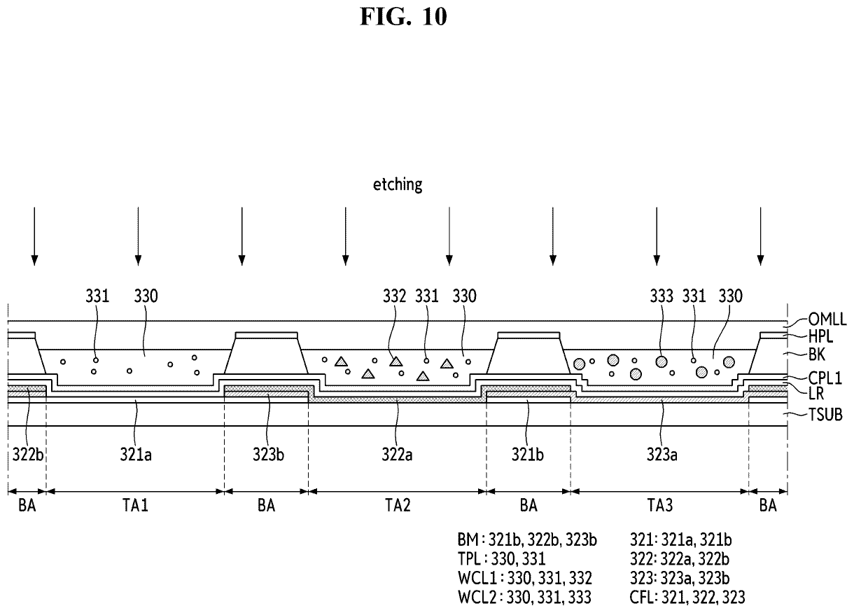

Next, referring to FIG. 10, an organic material layer OMLL may be formed on the bank BK and each light transmitting member TPL, WCL1 or WCL2. The organic material layer OMLL may be a layer for forming the organic layers OML illustrated in FIG. 5 and may be formed using a solution process such as spin coating or inkjet printing. The organic material layer OMLL may be formed to fully cover the bank BK, the hydrophobic layer HPL, and each light transmitting member TPL, WCL1 or WCL2.

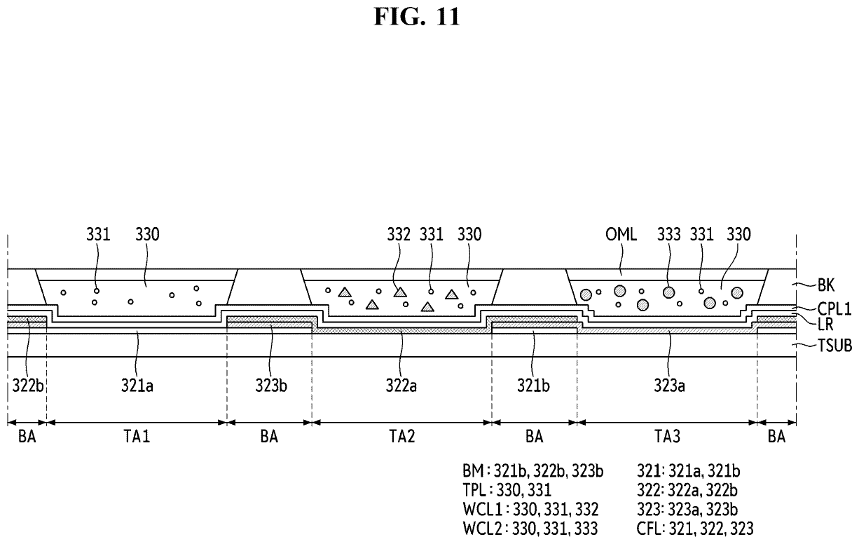

Next, referring to FIGS. 10 and 11, the hydrophobic layer HPL and a portion of the organic material layer OMLL are removed by etching. The etching process may be a dry etching process. According to the etching process, the organic material layer OMLL may be etched from its surface toward the counter substrate TSUB, and the hydrophobic layer HPL may also be etched and removed. In the etching process, the surface of the bank BK may also be partially etched to completely remove the hydrophobic layer HPL. Accordingly, the hydrophobic layer HPL and a portion of the organic material layer OMLL may be removed, and the organic material layer OMLL may be formed into the organic layers OML. Upper surfaces of the organic layers OML may be aligned (or coplanar) with the upper surface of the bank BK. The organic material layer OMLL described above may prevent each light transmitting member TPL, WCL1 or WCL2 from being damaged in the process of etching the hydrophobic layer HPL.

Although the hydrophobic layer HPL includes a perfluorinated compound (e.g., CF₃ chains), the perfluorinated compound may be prevented from remaining in the display device because the hydrophobic layer HPL is removed by the above etching process. Therefore, it is possible to respond to the demand for exclusion of perfluorinated compounds in the art to which the disclosure pertains.

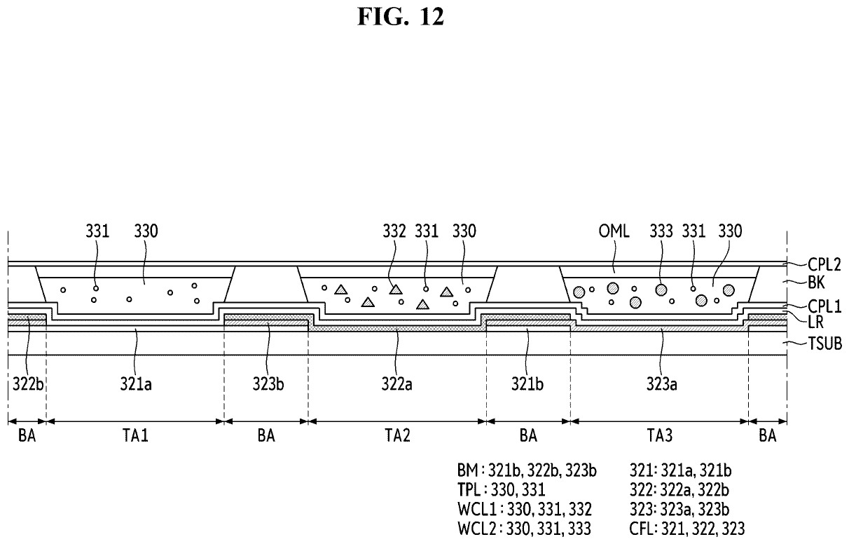

Next, referring to FIG. 12, a second capping layer CPL2 may be formed on the bank BK and the organic layers OML. The second capping layer CPL2 may be formed through a CVD or PVD process, like the first capping layer CPL1 described above.

Next, as illustrated in FIG. 5, a filling layer FIL may be applied onto the second capping layer CPL2, and a substrate SUB on which a light emitting element layer EML and a thin-film encapsulation layer TFEL are formed may be bonded to the counter substrate TSUB to produce the display device 10 according to the embodiment.

According to the above-described embodiment, since the process of forming the hydrophobic layer HPL on the bank BK and then removing the hydrophobic layer HPL is performed, it is possible to prevent a perfluorinated compound from remaining in the device. Since the organic material layer OMLL is formed on each light transmitting member TPL, WCL1 or WCL2, each light transmitting member TPL, WCL1 or WCL2 can be prevented from being damaged in the process of removing the hydrophobic layer HPL. Since the hydrophobic layer HPL is formed by performing a CF₄ plasma process under the above-described process conditions, the surface of the bank BK may exhibit hydrophobicity, and the surface of the first capping layer CPL1 between portions of the bank BK may exhibit hydrophilicity. Therefore, it is possible to improve the spreadability of each light-transmitting member material on the surface of the first capping layer CPL1 in case that each light-transmitting member material is applied and prevent each light-transmitting member material from overflowing from the surface of the bank BK to an adjacent light transmitting area.

Hereinafter, other embodiments of the display device 10 will be described with reference to other drawings.

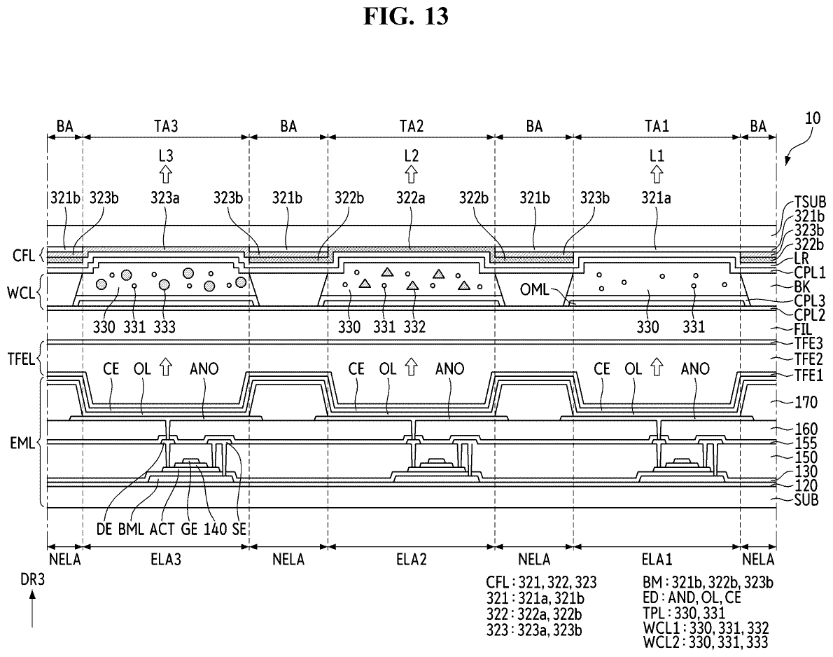

FIG. 13 is a schematic cross-sectional view of a display device according to an embodiment.

Referring to FIG. 13, the embodiment is different from the embodiment of FIG. 5 described above in that a third capping layer CPL3 is further disposed between each light transmitting member TPL, WCL1 or WCL2 and an organic layer OML. Therefore, a description of elements and features identical to those of the above-described embodiment will be omitted, and differences will be described below.

The third capping layer CPL3 may be disposed between each light transmitting member TPL, WCL1 or WCL2 and the organic layer OML between portions of a bank BK. The third capping layer CPL3 may contact (or directly contact) a surface of each light transmitting member TPL, WCL1 or WCL2 and a surface of the organic layer OML. The third capping layer CPL3 may extend to side surfaces of the bank BK while covering each light transmitting member TPL, WCL1 or WCL2. For example, the third capping layer CPL3 may cover each light transmitting member TPL, WCL1 or WCL2 to prevent each light transmitting member TPL, WCL1 or WCL2 from being damaged during a process.

In some embodiments, a lower surface of the third capping layer CPL3 (e.g., a surface of the third capping layer CPL3 which is closest to a substrate SUB) may be aligned (or coplanar) with a lower surface of the bank BK. The lower surface of the third capping layer CPL3 may contact (or directly contact) an upper surface of the second capping layer CPL2. In some embodiments, the third capping layer CPL3 may be surrounded by each light transmitting member TPL, WCL1 or WCL2, the organic layer OML, the bank BK, and the second capping layer CPL2.

The third capping layer CPL3 may include an inorganic material. In some embodiments, the third capping layer CPL3 may include an inorganic material such as SiO₂, SiNₓ or SiON and may be formed as a single layer or a multilayer, but the disclosure is not limited thereto.

Since the third capping layer CPL3 covering each light transmitting member TPL, WCL1 or WCL2 is included, each light transmitting member TPL, WCL1 or WCL2 can be prevented from being damaged during a process.

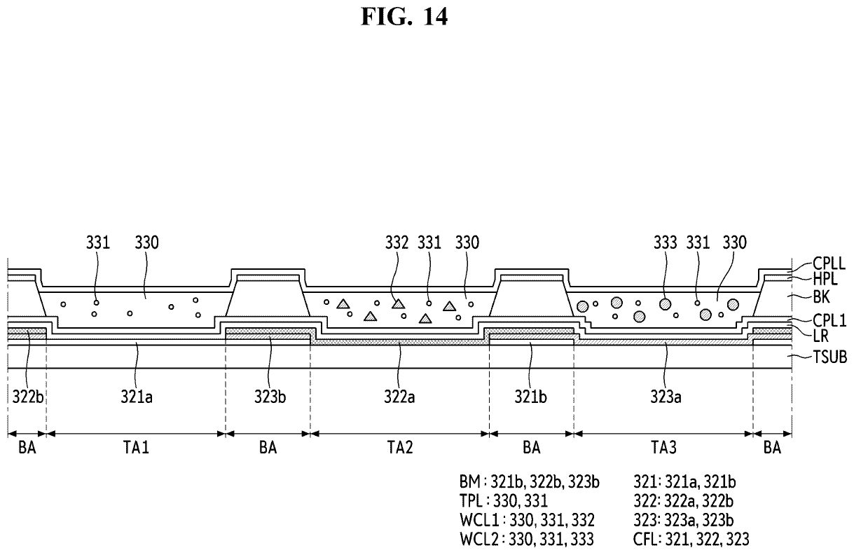

FIGS. 14 through 17 are schematic cross-sectional views illustrating each process in a method of manufacturing a display device according to an embodiment. FIGS. 14 through 17 illustrate a process of forming a color filter layer CFL and a wavelength conversion layer WCL on a counter substrate TSUB of FIG. 13.

The method of manufacturing a display device 10 according to the embodiment may include a process of forming third capping layers CPL3 in the manufacturing method described above with reference to FIGS. 6 through 12. For example, the method may include forming a capping material layer CPLL on a bank BK and each light transmitting member TPL, WCL1 or WCL2, forming an organic material layer OMLL on the capping material layer CPLL, forming organic layers OML and the third capping layers CPL3 by removing a hydrophobic layer HPL, a portion of the organic material layer OMLL and a portion of the capping material layer CPLL, and forming a second capping layer CPL2 on the bank BK, the organic layers OML and the third capping layers CPL3.

Referring to FIG. 14, a capping material layer CPLL may be formed on a bank BK and each light transmitting member TPL, WCL1 or WCL2. Before the capping material layer CPLL is formed, the bank BK, a hydrophobic layer HPL, and each light transmitting member TPL, WCL1 or WCL2 may be formed on a first capping layer CPL1 described above with reference to FIGS. 6 through 9. Since these processes are the same as the processes described above with reference to FIGS. 6 through 9, a redundant description thereof will be omitted.

The capping material layer CPLL may be formed through a CVD or PVD process, like the first capping layer CPL1 described above. The capping material layer CPLL may be formed to cover the bank BK, the hydrophobic layer HPL, and each light transmitting member TPL, WCL1 or WCL2.

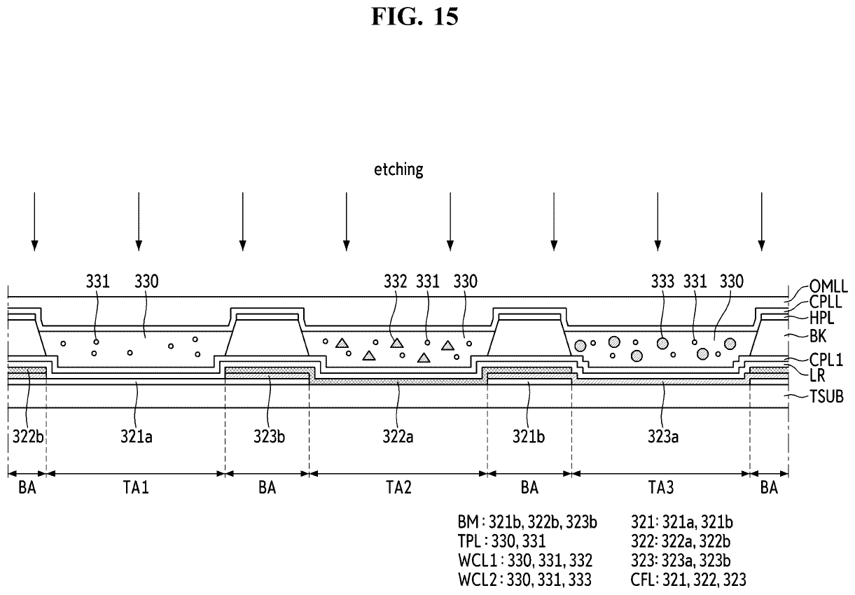

Next, referring to FIG. 15, an organic material layer OMLL may be formed on the capping material layer CPLL. The organic material layer OMLL may be a layer for forming the organic layers OML illustrated in FIG. 13 and may be formed using a solution process such as spin coating or inkjet printing. The organic material layer OMLL may be formed to a thickness sufficient to flatten a step of the capping material layer CPLL.

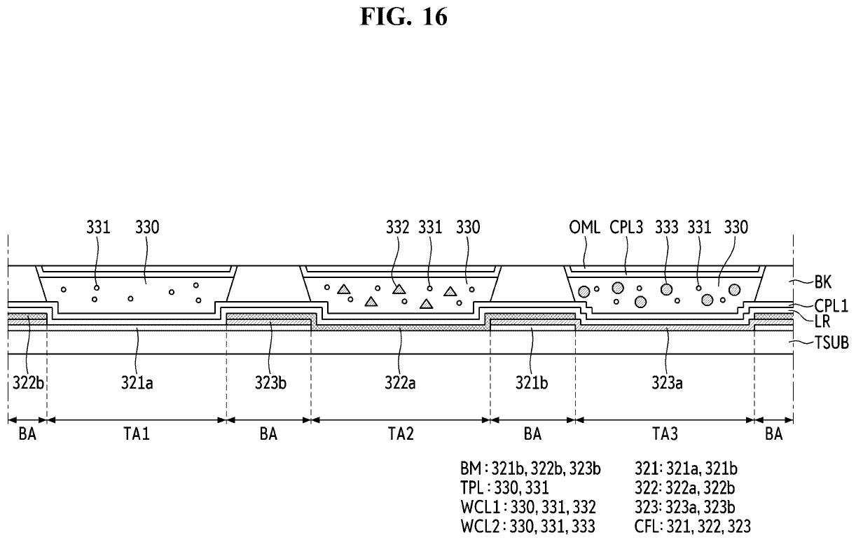

Next, referring to FIGS. 15 and 16, the hydrophobic layer HPL, a portion of the capping material layer CPLL, and a portion of the organic material layer OMLL may be removed by etching. According to the etching process, the organic material layer OMLL may be etched from its surface toward a counter substrate TSUB, and a portion of the capping material layer CPLL and the hydrophobic layer HPL may also be etched and removed. Accordingly, the hydrophobic layer HPL, a portion of the capping material layer CPLL, and a portion of the organic material layer OMLL may be removed to form the organic material layer OMLL into the organic layers OML and the capping material layer CPLL into the third capping layers CPL3. Upper surfaces of the organic layers OML may be aligned (or coplanar) with an upper surface of the bank BK and upper surfaces of the third capping layers CPL3. The organic material layer OMLL and the capping material layer CPLL described above may prevent each light transmitting member TPL, WCL1 or WCL2 from being damaged in the process of etching the hydrophobic layer HPL.

Although the hydrophobic layer HPL includes a perfluorinated compound (e.g., CF₃ chains), the perfluorinated compound may be prevented from remaining in the display device because the hydrophobic layer HPL is removed by the above etching process. Therefore, it is possible to respond to the demand for exclusion of perfluorinated compounds in the art to which the disclosure pertains.

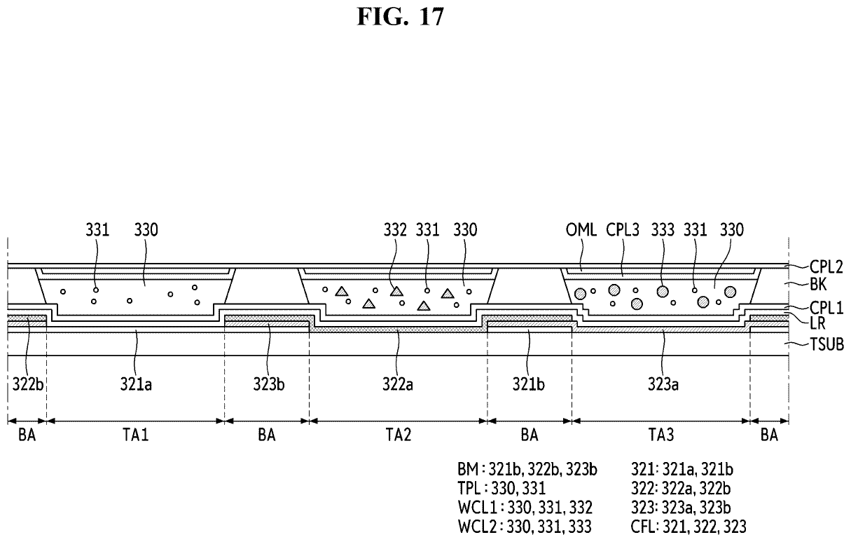

Next, referring to FIG. 17, a second capping layer CPL2 may be formed on the bank BK, the third capping layers CPL3, and the organic layers OML. As described above, a filling layer FIL may be formed on the second capping layer CPL2, and a substrate SUB on which a light emitting element layer EML and a thin-film encapsulation layer TFEL are formed may be bonded to the counter substrate TSUB to produce the display device 10 according to the embodiment illustrated in FIG. 13.

According to the above-described embodiment, since the capping material layer CPLL is formed on each light transmitting member TPL, WCL1 or WCL2, each light transmitting member TPL, WCL1 or WCL2 can be prevented from being damaged in the process of removing the hydrophobic layer HPL.

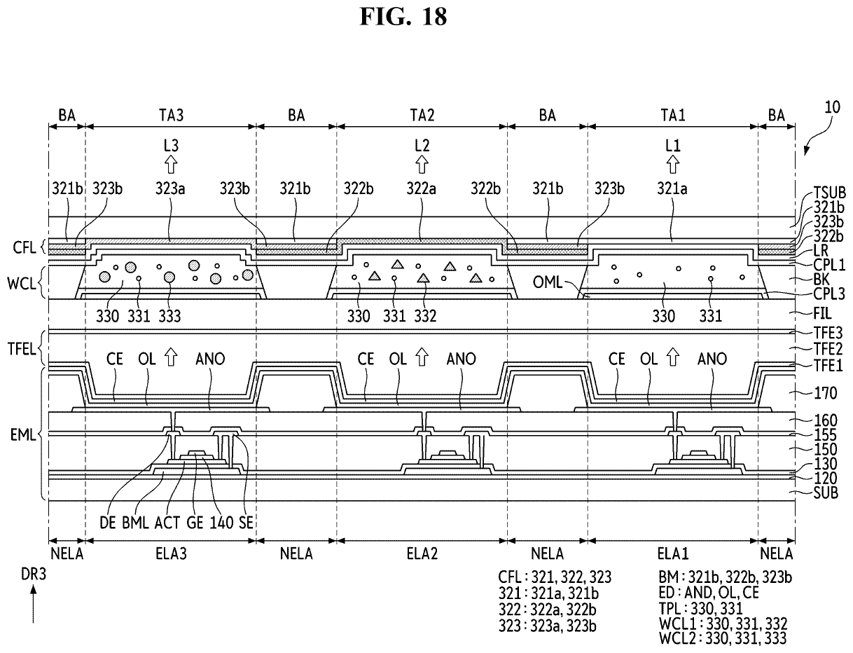

FIG. 18 is a schematic cross-sectional view of a display device according to an embodiment.

Referring to FIG. 18, the embodiment is different from the embodiment of FIG. 13 described above in that a second capping layer CPL2 is omitted. Since the second capping layer CPL2 is omitted, a bank BK, third capping layers CPL3, and organic layers OML may contact (or directly contact) a filling layer FIL. Since each light transmitting member TPL, WCL1 or WCL2 is covered and protected by a third capping layer CPL3, the second capping layer CPL2 can be omitted.

The display device illustrated in FIG. 18 may be manufactured by omitting the process of forming the second capping layer CPL2 in FIG. 17 described above.

The omission of the second capping layer CPL2 can simplify the manufacturing process and reduce the manufacturing cost.

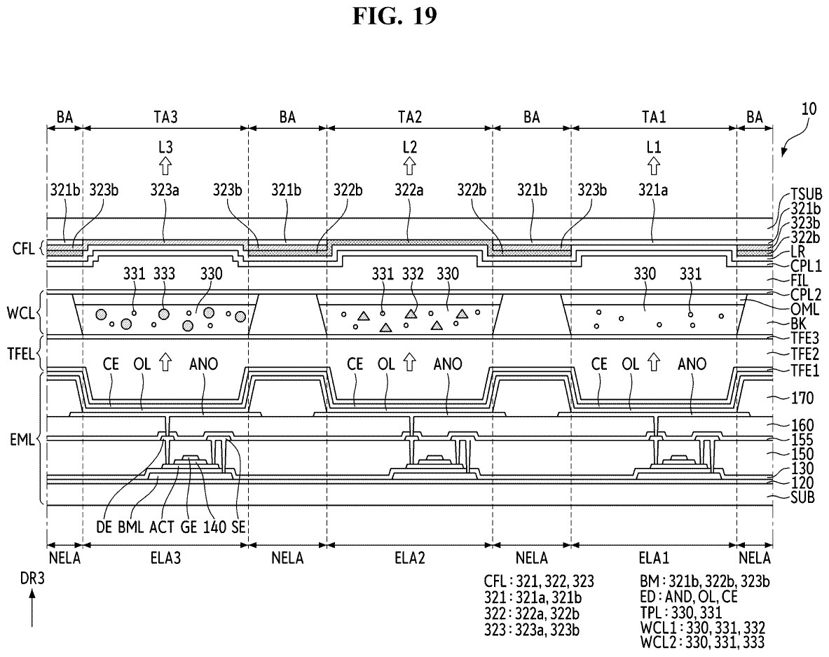

FIG. 19 is a schematic cross-sectional view of a display device 10 according to an embodiment.

Referring to FIG. 19, the display device 10 according to the embodiment is different from those according to the embodiments of FIGS. 5 through 18 described above in that a wavelength conversion layer WCL is disposed (or directly disposed) on a thin-film encapsulation layer TFEL. Therefore, a description of elements and features identical to those of the above-described embodiments will be omitted, and differences will be described below.

The wavelength conversion layer WCL may be disposed on the thin-film encapsulation layer TFEL. The wavelength conversion layer WCL may include a bank BK, a first light transmitting member TPL, a second light transmitting member WCL1, a third light transmitting member WCL2, organic layers OML, and a second capping layer CPL2.

The bank BK may be disposed on a third encapsulation layer TFE3 of the thin-film encapsulation layer TFEL to form spaces for accommodating light transmitting members. The bank BK may surround each light transmitting member TPL, WCL1 or WCL2 in a plan view. The bank BK may overlap a non-light emitting area NELA and a light blocking area BA. The bank BK may not overlap light emitting areas ELA1 through ELA3 and light transmitting areas TA1 through TA3.

The first light transmitting member TPL may be disposed on the third encapsulation layer TFE3 in a space defined by the bank BK and may overlap a first light emitting area ELA1 and a first light transmitting area TA1 in the third direction DR3. The first light transmitting member TPL may contact (or directly contact) the third encapsulation layer TFE3 and the bank BK. The first light transmitting member TPL may include a base resin 330 and light scatterers 331.

The second light transmitting member WCL1 may be disposed on the third encapsulation layer TFE3 in a space defined by the bank BK and may overlap a second light emitting area ELA2 and a second light transmitting area TA2 in the third direction DR3. The second light transmitting member WCL1 may contact (or directly contact) the third encapsulation layer TFE3 and the bank BK. The second light transmitting member WCL1 may include a base resin 330, light scatterers 331 dispersed in the base resin 330, and first wavelength shifters 332 dispersed in the base resin 330.

The third light transmitting member WCL2 may be disposed on the third encapsulation layer TFE3 in a space defined by the bank BK and may overlap a third light emitting area ELA3 and a third light transmitting area TA3 in the third direction DR3. The third light transmitting member WCL2 may contact (or directly contact) the third encapsulation layer TFE3 and the bank BK. The third light transmitting member WCL2 may include a base resin 330, light scatterers 331 dispersed in the base resin 330, and second wavelength shifters 333 dispersed in the base resin 330.

The organic layers OML may be respectively located in the light transmitting areas TA1, TA2 and TA3 defined by the bank BK. For example, the organic layers OML may overlap the first light transmitting area TA1, the second light transmitting area TA2, and the third light transmitting area TA3. The organic layers OML may be located in a patterned shape and may be disposed (or directly disposed) on the light transmitting members TPL, WCL1 and WCL2, respectively in the third direction DR3. The organic layers OML may protect the light transmitting members TPL, WCL1 and WCL2 from being etched during a manufacturing process which will be described later. The organic layers OML may be spaced apart from an upper surface of the bank BK and may not cover (or overlap) the bank BK. For example, upper surfaces of the organic layers OML may be aligned (or coplanar) with the upper surface of the bank BK.

In some embodiments, a height of the upper surface of the bank BK measured from the thin-film encapsulation layer TFEL may be equal to a height of the upper surfaces of the organic layers OML. For example, the upper surface of the bank BK and the upper surfaces of the organic layers OML may be aligned (or coplanar) with each other, for example, may be disposed on the same plane (or the same layer).

The second capping layer CPL2 may be disposed on the bank BK and the organic layers OML to cover the bank BK and the organic layers OML. The second capping layer CPL2 may prevent damage to or contamination of each light transmitting member TPL, WCL1 or WLC2 and the organic layers OML by preventing penetration of impurities such as moisture or air from the outside into each light transmitting member TPL, WCL1 or WLC2 and the organic layers OML. The second capping layer CPL2 may be formed flat without a step. Since the upper surfaces of the bank BK and the organic layers OML are aligned (or coplanar) with each other, the second capping layer CPL2 formed on the surfaces may be flat. In some embodiments, the second capping layer CPL2 may contact (or directly contact) the upper surface of the bank BK and the upper surfaces of the organic layers OML.

A color filter layer CFL, a low refractive layer LR, and a first capping layer CPL1 may be sequentially disposed on a surface of a counter substrate TSUB. A filling layer FIL may be disposed between the counter substrate TSUB and a substrate SUB. The filling layer FIL may be interposed between the first capping layer CPL1 and the second capping layer CPL2 of the wavelength conversion layer WCL to fill a space between the first capping layer CPL1 and the second capping layer CPL2 of the wavelength conversion layer WCL. In some embodiments, the filling layer FIL may contact (or directly contact) the first capping layer CPL1 and the second capping layer CPL2 of the wavelength conversion layer WCL, but the disclosure is not limited thereto.

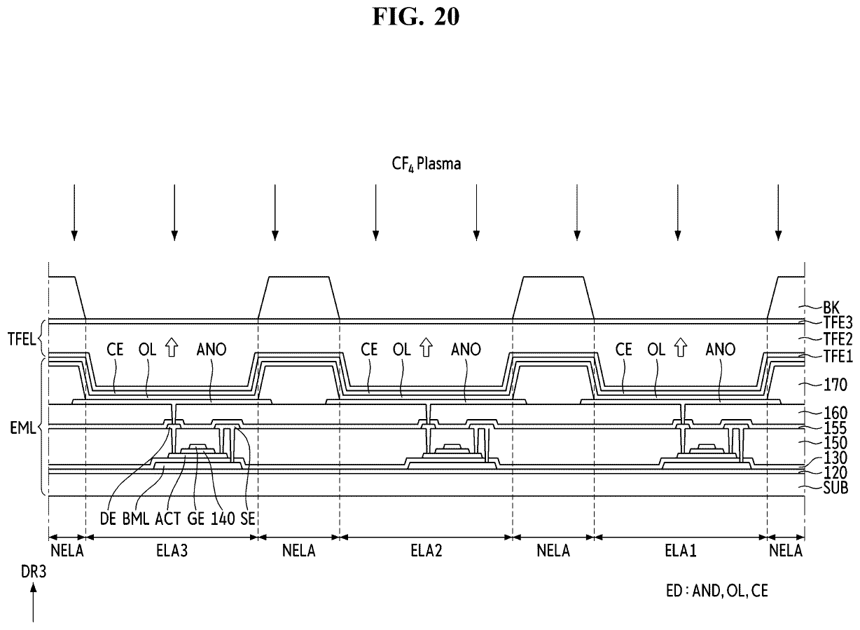

A method of manufacturing a display device according to FIG. 19 described above will now be described with reference to FIGS. 20 through 25. In the manufacturing method to be described below, the same processes as those of the manufacturing method described above with reference to FIGS. 6 through 12 may be described briefly or may not be described.

FIGS. 20 through 25 are schematic cross-sectional views illustrating each process in a method of manufacturing a display device according to an embodiment. The manufacturing method of FIGS. 20 through 25 is a method of manufacturing a display device corresponding to FIG. 19 described above.

The method of manufacturing a display device 10 according to the embodiment may include forming a bank BK on a thin-film encapsulation layer TFEL, forming a hydrophobic layer HPL on the bank BK, forming each light transmitting member TPL, WCL1 or WCL2 between portions of the bank BK, forming an organic material layer OMLL on the bank BK and each light transmitting member TPL, WCL1 or WCL2, forming organic layers OML by removing the hydrophobic layer HPL and a portion of the organic material layer OMLL, and forming a second capping layer CPL2 on the bank BK and the organic layers OML.

Firstly, referring to FIG. 20, a substrate SUB on which a light emitting element layer EML and a thin-film encapsulation layer TFEL are formed may be prepared. The light emitting element layer EML and the thin-film encapsulation layer TFEL may be formed by stacking each layer on the substrate SUB or by patterning each layer using a photo process after stacking each layer.

Next, a bank BK may be formed on the thin-film encapsulation layer TFEL. The bank BK may be formed on a third encapsulation layer TFE3 to overlap a non-light emitting area NELA and not overlap each light emitting area ELA1, ELA2 or ELA3.

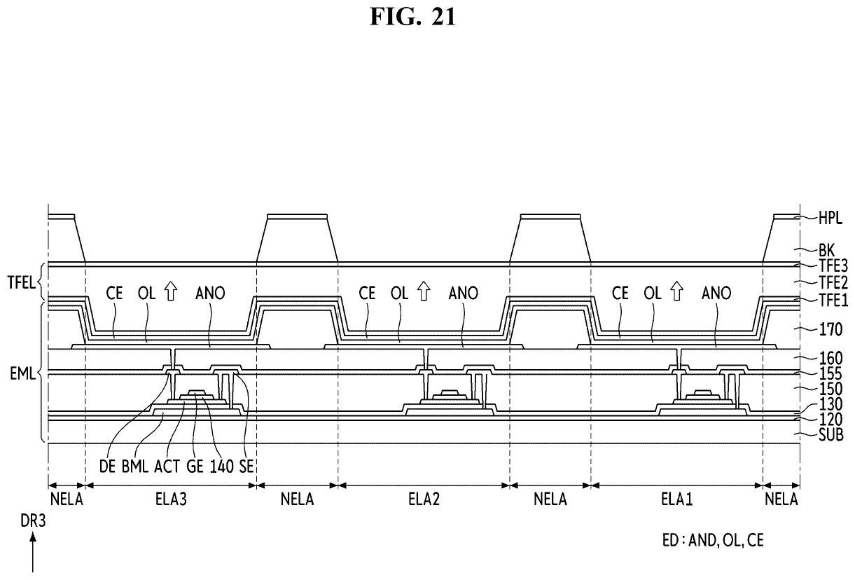

Next, referring to FIGS. 20 and 21, a hydrophobic layer HPL may be formed on the bank BK. For example, the hydrophobic layer HPL may be formed by performing an ashing process and a plasma process on the substrate SUB on which the bank BK is formed. Since the ashing and plasma processes for forming the hydrophobic layer HPL have been described above in detail in the embodiment of FIGS. 6 through 12, a description thereof will be omitted.

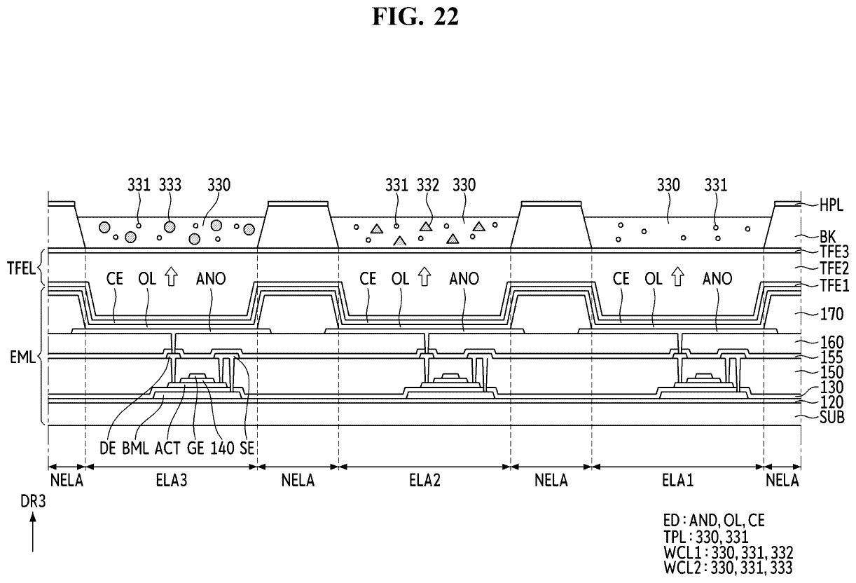

Next, referring to FIG. 22, a first light transmitting member TPL, a second light transmitting member WCL1, and a third light transmitting member WCL2 are respectively formed in the light emitting areas ELA1 through ELA3 formed between portions of the bank BK.

Since the hydrophobic layer HPL is disposed on an upper surface of the bank BK, in case that each light-transmitting member material is applied to a corresponding light transmitting area, it can be prevented from overflowing from the light transmitting area to other adjacent light transmitting areas beyond the bank BK.

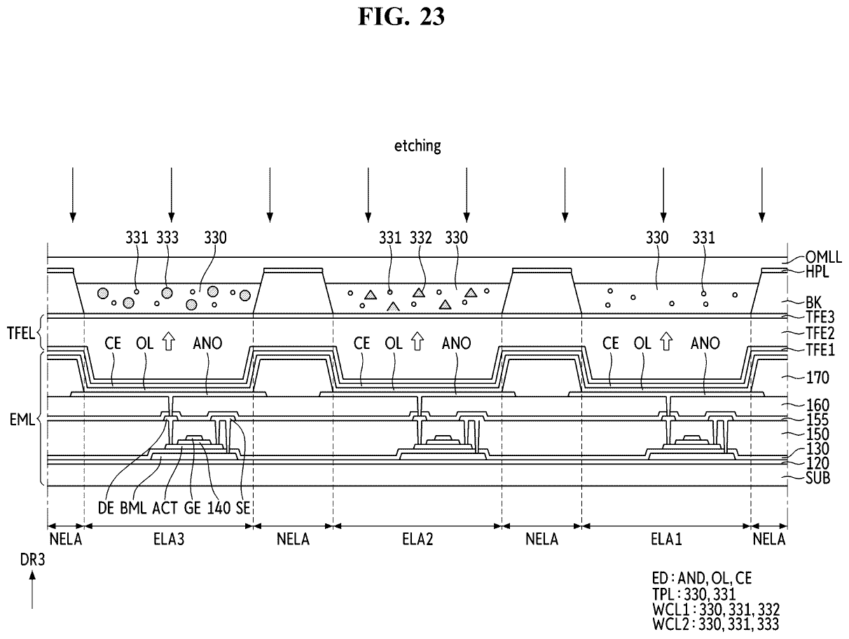

Next, referring to FIG. 23, an organic material layer OMLL may be formed on the bank BK and each light transmitting member TPL, WCL1 or WCL2. The organic material layer OMLL may be formed to fully cover the bank BK, the hydrophobic layer HPL, and each light transmitting member TPL, WCL1 or WCL2.

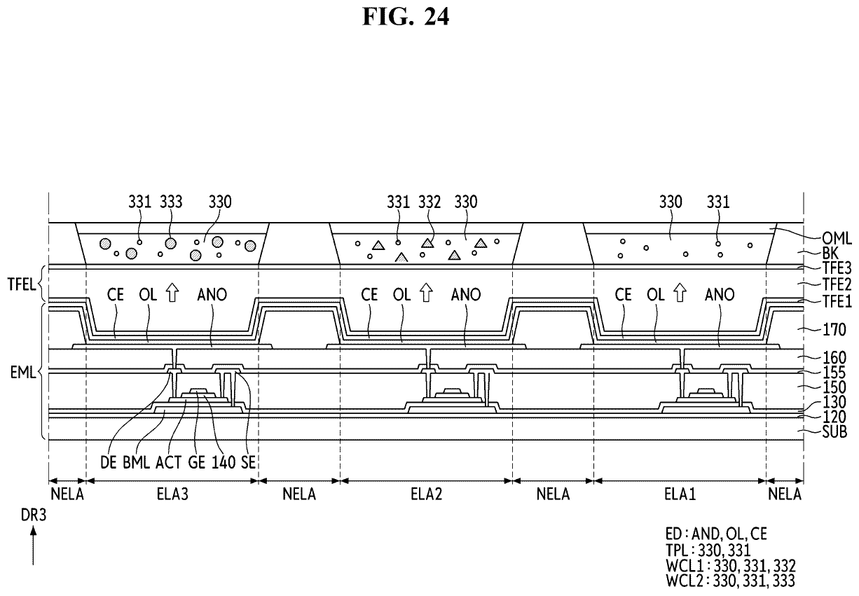

Next, referring to FIGS. 23 and 24, the hydrophobic layer HPL and a portion of the organic material layer OMLL may be removed by etching. According to the etching process, the organic material layer OMLL may be etched from its surface toward the substrate SUB, and the hydrophobic layer HPL may also be etched and removed. Accordingly, the hydrophobic layer HPL and a portion of the organic material layer OMLL may be removed to form the organic material layer OMLL into organic layers OML. Upper surfaces of the organic layers OML may be aligned (or coplanar) with the upper surface of the bank BK. The organic material layer OML described above may prevent each light transmitting member TPL, WCL1 or WCL2 from being damaged in the process of etching the hydrophobic layer HPL.

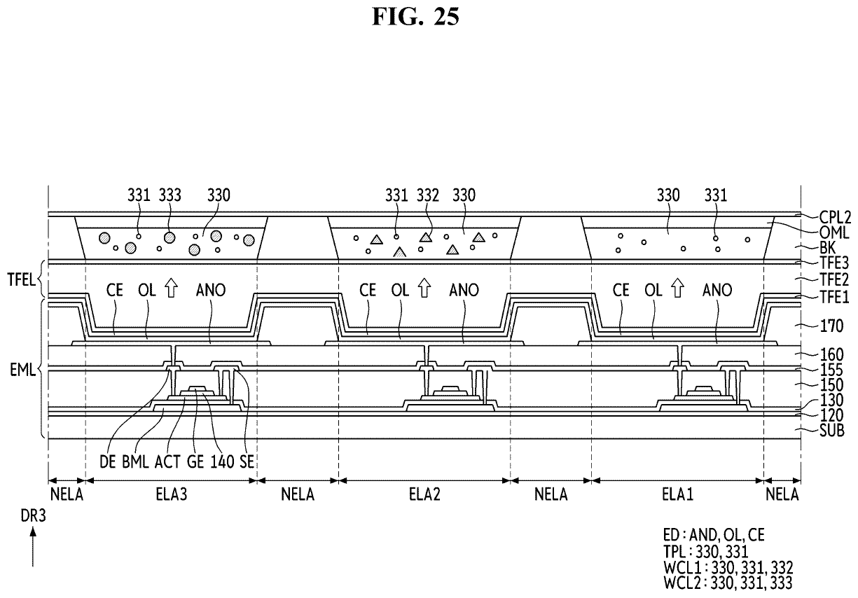

Next, referring to FIG. 25, a second capping layer CPL2 may be formed on the bank BK and the organic layers OML.

Next, as illustrated in FIG. 19, a filling layer FIL may be formed on a counter substrate TSUB on which a color filter layer CFL, a low refractive layer LR and a first capping layer CPL1 are formed and may be bonded to the substrate SUB to produce the display device 10 according to the embodiment.

Other embodiments of the display device 10 will now be described with reference to other drawings.

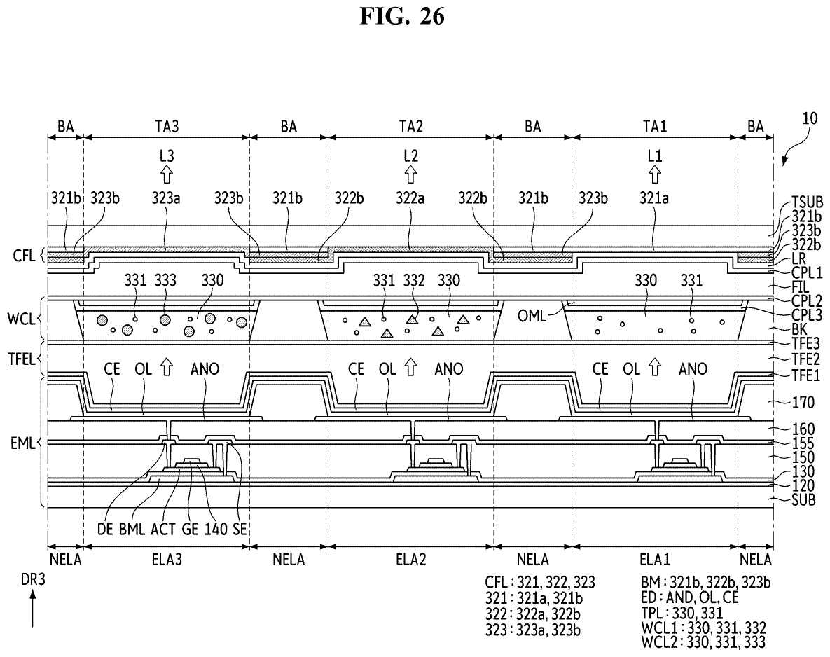

FIG. 26 is a schematic cross-sectional view of a display device according to an embodiment.

Referring to FIG. 26, the embodiment is different from the embodiment of FIG. 19 described above in that a third capping layer CPL3 is further disposed between each light transmitting member TPL, WCL1 or WCL2 and an organic layer OML. Therefore, a description of elements and features identical to those of the above-described embodiment will be omitted, and differences will be described below.

The third capping layer CPL3 may be disposed between each light transmitting member TPL, WCL1 or WCL2 and the organic layer OML between portions of a bank BK. The third capping layer CPL3 may contact (or directly contact) a surface of each light transmitting member TPL, WCL1 or WCL2 and a surface of the organic layer OML. The third capping layer CPL3 may extend to side surfaces of the bank BK while covering each light transmitting member TPL, WCL1 or WCL2. For example, the third capping layer CPL3 may cover each light transmitting member TPL, WCL1 or WCL2 to prevent each light transmitting member TPL, WCL1 or WCL2 from being damaged during a process.

In some embodiments, an upper surface of the third capping layer CPL3 may be aligned (or coplanar) with an upper surface of the bank BK. The upper surface of the third capping layer CPL3 may contact (or directly contact) a lower surface of a second capping layer CPL2. In some embodiments, the third capping layer CPL3 may be surrounded by each light transmitting member TPL, WCL1 or WCL2, the organic layer OML, the bank BK, and the second capping layer CPL2.

Since the third capping layer CPL3 covering each light transmitting member TPL, WCL1 or WCL2 is included, each light transmitting member TPL, WCL1 or WCL2 can be prevented from being damaged during a process.

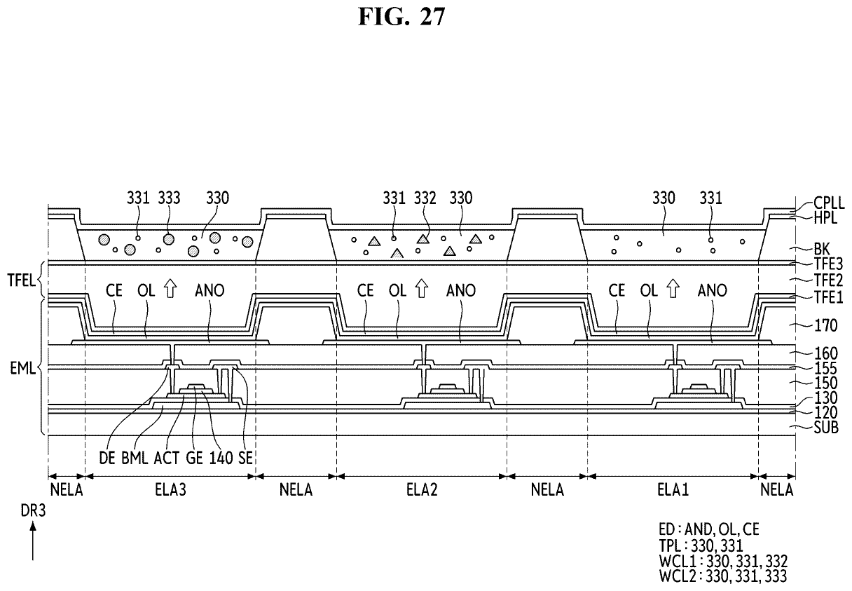

FIGS. 27 through 30 are schematic cross-sectional views illustrating each process in a method of manufacturing a display device according to an embodiment. FIGS. 27 through 30 illustrate a process of forming a wavelength conversion layer WCL on a thin-film encapsulation layer TFEL of FIG. 26.

The method of manufacturing a display device 10 according to the embodiment may include a process of forming third capping layers CPL3 in the manufacturing method described above with reference to FIGS. 20 through 25. For example, the method may include forming a capping material layer CPLL on a bank BK and each light transmitting member TPL, WCL1 or WCL2, forming an organic material layer OMLL on the capping material layer CPLL, forming organic layers OML and the third capping layers CPL3 by removing a hydrophobic layer HPL, a portion of the organic material layer OMLL and a portion of the capping material layer CPLL, and forming a second capping layer CPL2 on the bank BK, the organic layers OML and the third capping layers CPL3.

Referring to FIG. 27, a capping material layer CPLL may be formed on a bank BK and each light transmitting member TPL, WCL1 or WCL2. Before the capping material layer CPLL is formed, a bank BK, a hydrophobic layer HPL, and each light transmitting member TPL, WCL1 or WCL2 are formed on the third encapsulation layer TFE3 of the thin-film encapsulation layer TFEL described above with reference to FIGS. 20 through 23. Since these processes are the same as the processes described above with reference to FIGS. 20 through 23, a redundant description thereof will be omitted. The capping material layer CPLL may be formed to cover the bank BK, the hydrophobic layer HPL, and each light transmitting member TPL, WCL1 or WCL2.

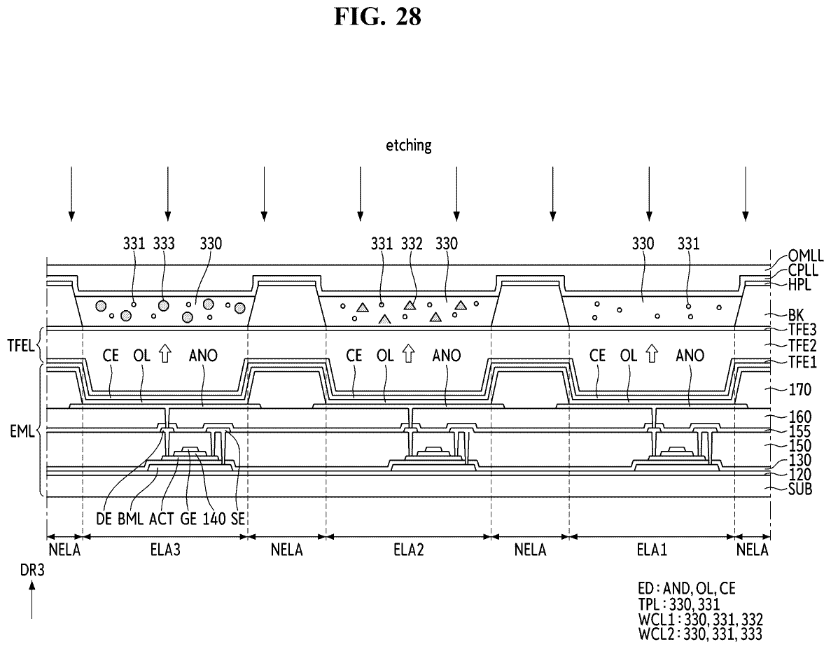

Next, referring to FIG. 28, an organic material layer OMLL may be formed on the capping material layer CPLL. The organic material layer OMLL may be a layer for forming the organic layers OML illustrated in FIG. 26 and may be formed using a solution process such as spin coating or inkjet printing. The organic material layer OMLL may be formed to a thickness sufficient to flatten a step of the capping material layer CPLL.

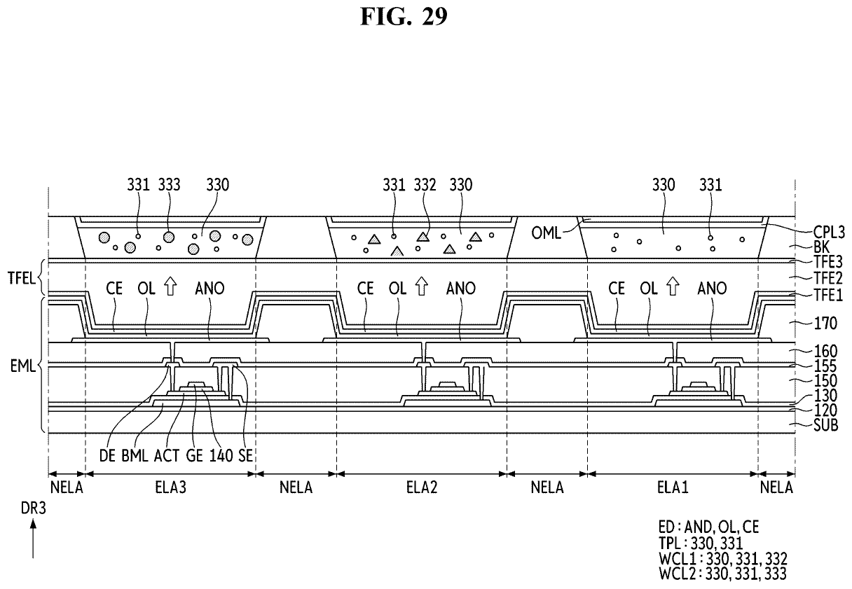

Next, referring to FIGS. 28 and 29, the hydrophobic layer HPL, a portion of the capping material layer CPLL, and a portion of the organic material layer OMLL may be removed by etching. According to the etching process, the organic material layer OMLL may be etched from its surface toward a substrate SUB, and a portion of the capping material layer CPLL and the hydrophobic layer HPL may also be etched and removed. Accordingly, the hydrophobic layer HPL, a portion of the capping material layer CPLL, and a portion of the organic material layer OMLL may be removed to form the organic material layer OMLL into the organic layers OML and the capping material layer CPLL into third capping layers CPL3. Upper surfaces of the organic layers OML may be aligned (or coplanar) with an upper surface of the bank BK and upper surfaces of the third capping layers CPL3. The organic material layer OMLL and the capping material layer CPLL described above may prevent each light transmitting member TPL, WCL1 or WCL2 from being damaged in the process of etching the hydrophobic layer HPL.

Next, referring to FIG. 29, a second capping layer CPL2 may be formed on the bank BK, the third capping layers CPL3, and the organic layers OML. A filling layer FIL may be formed on a counter substrate TSUB on which a color filter layer CFL, a low refractive layer LR and a first capping layer CPL1 are formed and may be bonded to the substrate SUB to produce the display device 10 according to the embodiment.

According to the above-described embodiment, since the capping material layer CPLL is formed on each light transmitting member TPL, WCL1 or WCL2, each light transmitting member TPL, WCL1 or WCL2 can be prevented from being damaged in the process of removing the hydrophobic layer HPL.

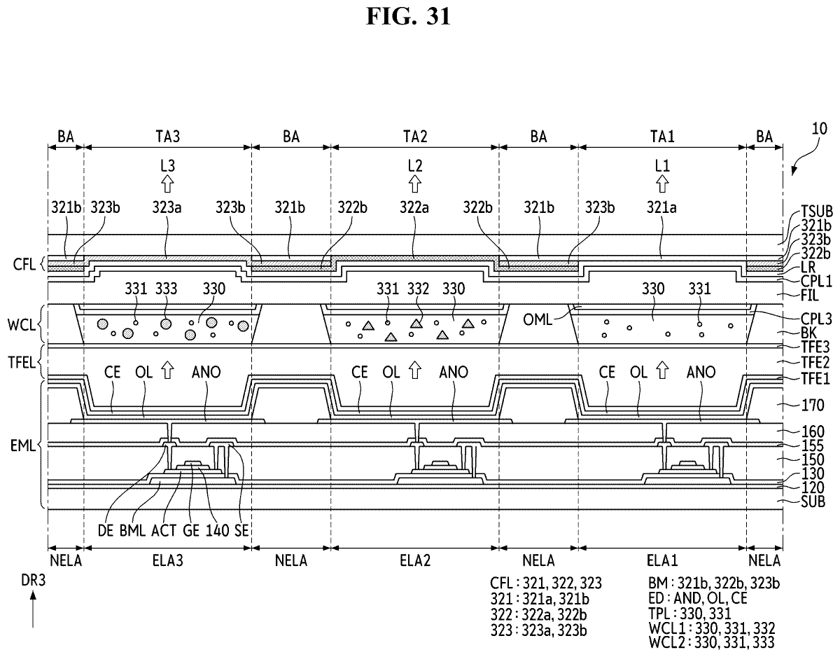

FIG. 31 is a schematic cross-sectional view of a display device according to an embodiment.

Referring to FIG. 31, the embodiment is different from the embodiment of FIG. 26 described above in that a second capping layer CPL2 is omitted. Since the second capping layer CPL2 is omitted, a bank BK, third capping layers CPL3, and organic layers OML may contact (or directly contact) a filling layer FIL. Since each light transmitting member TPL, WCL1 or WCL2 is covered and protected by a third capping layer CPL3, the second capping layer CPL2 can be omitted.

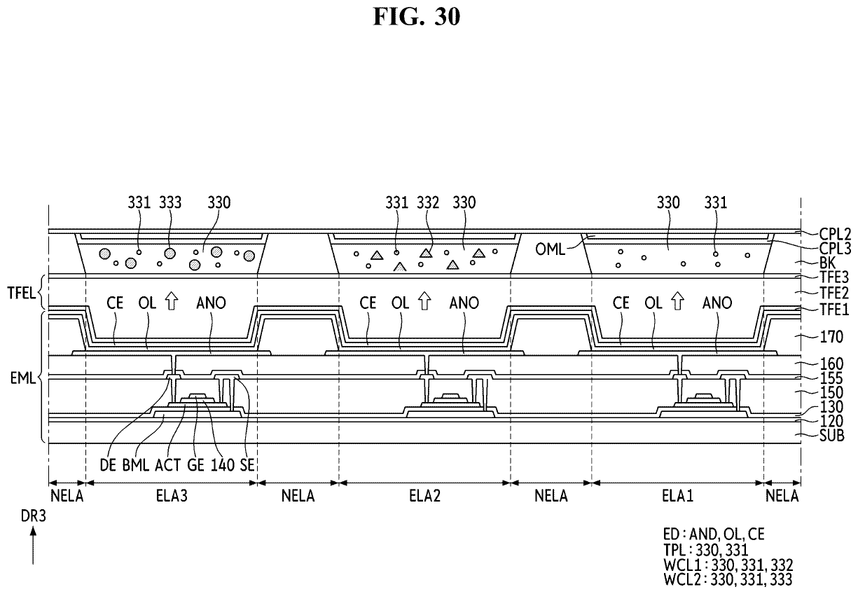

The display device illustrated in FIG. 31 may be manufactured by omitting the process of forming the second capping layer CPL2 in FIG. 30 described above.

The omission of the second capping layer CPL2 can simplify the manufacturing process and reduce the manufacturing cost.

Hereinafter, experimental examples of the disclosure will be described.

### Experimental Example 1

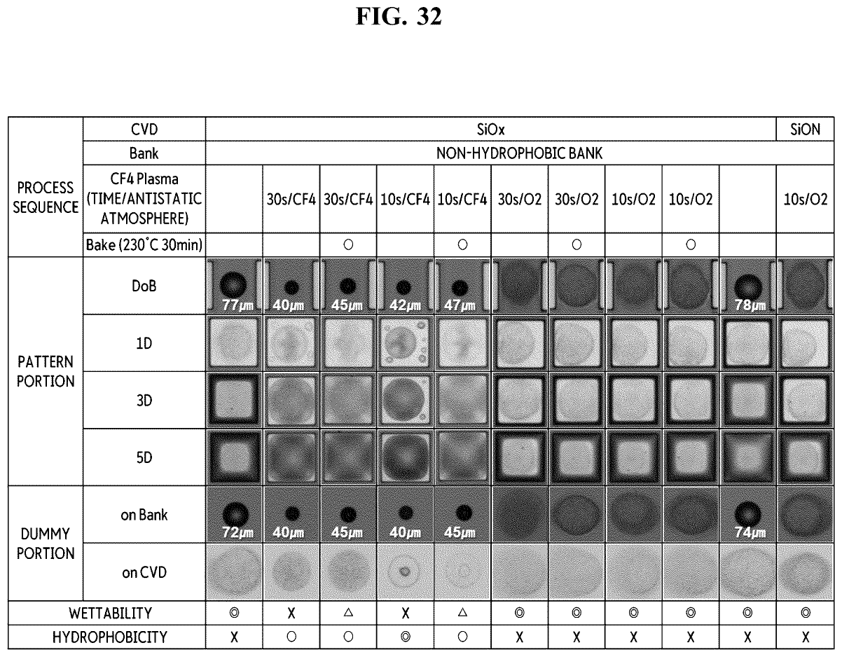

After a SiOₓ or SiON thin layer are formed on a glass substrate, a bank may be formed on the thin layer. Then, a CF₄ plasma process and an antistatic process were performed under different conditions (gas and time). After the antistatic process, a bake process was optically performed. Then, different amounts of light-transmitting member ink were dropped onto a pattern portion, a bank surface, and a dummy portion (an outermost area without a bank) separated by the bank, and images of the ink were measured and are shown in FIG. 32. The CF₄ plasma process and the antistatic process were performed under the conditions of 100 mTorr pressure and 500 W power.

FIG. 32 is a schematic diagram showing images of the ink formed according to Experimental Example 1. In FIG. 32, CVD represents the material of the thin layer formed on the glass substrate, DoB represents the bank surface, and 1D, 3D and 5D represent the numbers of ink droplets. The degree of excellence in wettability and hydrophobicity are indicated in the order of X, Δ, O, and ⊚.

Referring to FIG. 32, in a case where the bank are formed on the SiOₓ thin layer, both wettability and hydrophobicity are better in case that the CF₄ plasma process is performed for 30 seconds or 10 seconds, the antistatic process may be performed in a CF₄ atmosphere, and the bake process may be performed than in other examples. In case that the antistatic process is performed in an O₂ atmosphere, the hydrophobicity given by CF₄ plasma may be lost (or completely lost).

### Experimental Example 2

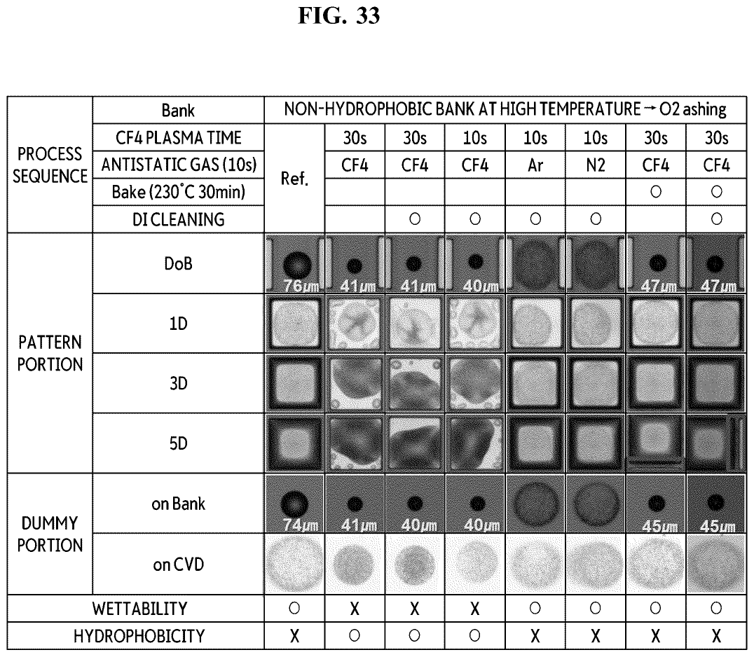

Under the same conditions as those in Experimental Example 1, an O₂ ashing process may be performed for 60 seconds immediately after a bank are formed, and a deionized (DI) water cleaning process may be optionally performed. The O₂ ashing process may be performed for about 60 seconds. The results are shown in FIG. 33.

FIG. 33 is a schematic diagram showing images of ink formed according to Experimental Example 2. In FIG. 33, Ref may represent a case where a CF₄ plasma process, an antistatic process, a bake process, and the DI water cleaning process are not performed after the bank are formed.

Referring to FIG. 33, even if the O₂ ashing process are performed, the wettability of a pattern portion may not be improved. It is found that the hydrophobicity of an upper portion of the bank may be lost in case that the antistatic process are performed in an Ar or N₂ atmosphere after the CF₄ plasma process. It is found that the hydrophobicity of the pattern portion was reduced in case that the bake process is performed after the CF₄ plasma process.

### Experimental Example 3

A SiON thin layer or a SiOₓ thin layer may be formed on a glass substrate. A bank may be formed on the thin layer, and then an O₂ ashing process, a CF₄ plasma process, a CF₄ antistatic process, and a bake process may be selectively performed to produce multiple samples. Then, light-transmitting member ink may be dropped onto a pixel portion defined by the bank and a bank surface DOB.

Sample #127F may be produced by performing the O₂ ashing process for 30 seconds, performing the CF₄ plasma process at a pressure of 100 mTorr and a power of 500 W for 30 seconds, and performing the antistatic process at a pressure of 100 mTorr and in a CF₄ atmosphere for 30 seconds.

Sample #80F may be produced by performing the CF₄ plasma process for 10 seconds under the same conditions as those for sample #127F.

Sample #74F may be produced by performing the O₂ ashing process for 60 seconds under the same conditions as those for sample #127F and omitting the CF₄ plasma process.

Sample #73F may be produced by performing the O₂ ashing process for 60 seconds under the same conditions as those for sample #127F, omitting the CF₄ plasma process, and performing the antistatic process at a pressure of 70 mTorr.

Sample #72F may be produced by performing the O₂ ashing process for 60 seconds under the same conditions as those for sample #127F, omitting the CF₄ plasma process, and performing the antistatic process at a pressure of 30 mTorr.

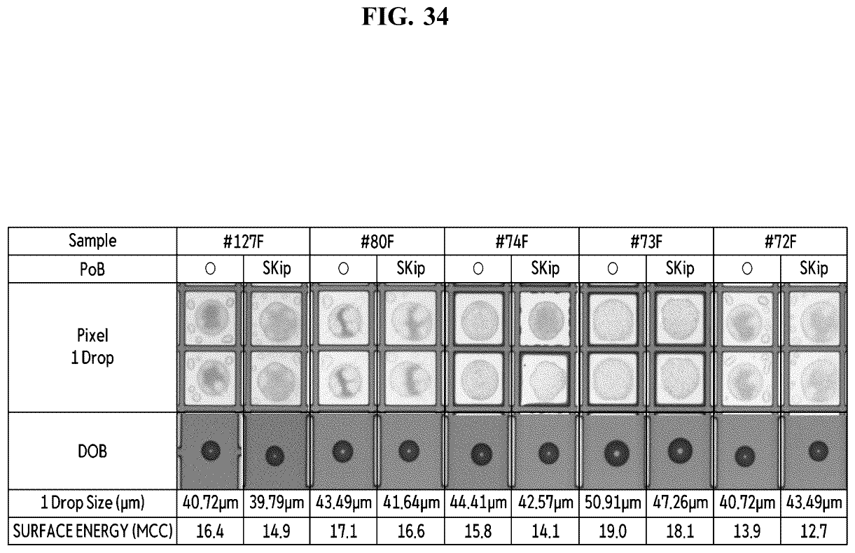

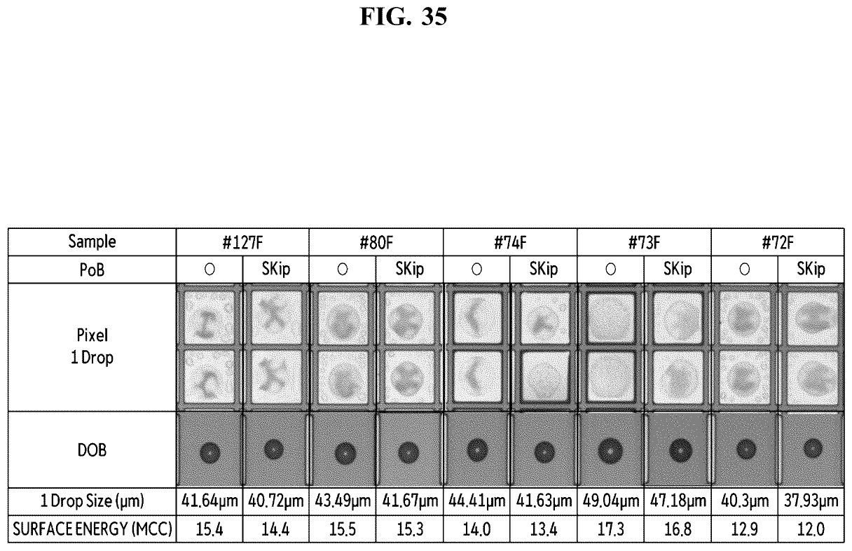

The images and sizes of ink drops on the above samples and the surface energy of the bank surface may be measured and are shown in FIGS. 34 and 35. FIGS. 34 and 35 are schematic diagrams showing the images and sizes of ink drops on the above samples according to Experimental Example 3 and the surface energy of the bank surface. FIG. 34 shows a case where the bank was formed on the SiON thin layer, and FIG. 35 shows a case where the bank was formed on the SiOₓ thin layer.

Referring to FIG. 34, it is found that samples #74F and #73F produced by omitting the CF₄ plasma process may show better spreadability of ink drops on the SiON thin layer of the pixel portion than samples #127F and #80F produced by performing the CF₄ plasma process. It is found that all samples may have hydrophobicity on the bank surface.

Referring to FIG. 35, it is found that samples #74F and #73F produced by omitting the CF₄ plasma process may show better spreadability of ink drops on the SiOₓ thin layer of the pixel portion than samples #127F and #80F produced by performing the CF₄ plasma process. It is found that all samples may have hydrophobicity on the bank surface.

As is apparent from the results of Experimental Example 3, in case that the CF₄ plasma process and the bake process are omitted and the O₂ ashing process and the CF₄ antistatic process are performed, excellent hydrophobicity may be given to the bank surface, and excellent wettability may be given to the pixel portion (the surface of the SiOₓ or SiON thin layer) defined by the bank.

The embodiments of FIGS. 5 through 31 described above disclose the process of forming the hydrophobic layer HPL on the surface of the bank BK by performing an ashing process and a plasma process. The ashing process may correspond to the O₂ ashing process of Experimental Example 3, and the plasma process may correspond to the CF₄ antistatic process of Experimental Example 3.

In the disclosure, the ashing process and the plasma process may be performed on the bank BK to give excellent hydrophobicity to the surface of the bank BK and excellent wettability to the light transmitting areas TA1 through TA3 separated by the bank BK. Accordingly, in case that each light transmitting member TPL, WCL1 or WCL2 is formed, a light-transmitting member material (ink) can be prevented from overflowing to an adjacent light transmitting area.

In a display device and a method of manufacturing the display device according to an embodiment and an electronic device, a process of forming a hydrophobic layer on a bank and then removing the hydrophobic layer is performed. Therefore, it is possible to prevent a perfluorinated compound from remaining in the device.

Since an organic material layer is formed on each light transmitting member, each light transmitting member can be prevented from being damaged in the process of removing the hydrophobic layer.

Since the hydrophobic layer is formed by performing a CF₄ plasma process under specific process conditions, a surface of the bank may exhibit hydrophobicity, and a surface of a capping layer between portions of the bank may exhibit hydrophilicity. Therefore, it is possible to improve the spreadability of each light-transmitting member material on the surface of the capping layer in case that each light-transmitting member material is applied and prevent each light-transmitting member material from overflowing from the surface of the bank to an adjacent light transmitting area.

However, the effects of the disclosure are not restricted to the one set forth herein. The above and other effects of the disclosure will become more apparent to one of daily skill in the art to which the disclosure pertains by referencing the claims.

The display device according to one embodiment of the disclosure can be applied to various electronic devices. The electronic device according to the one embodiment of the disclosure may include the display device described above, and may further include modules or devices having additional functions in addition to the display device.

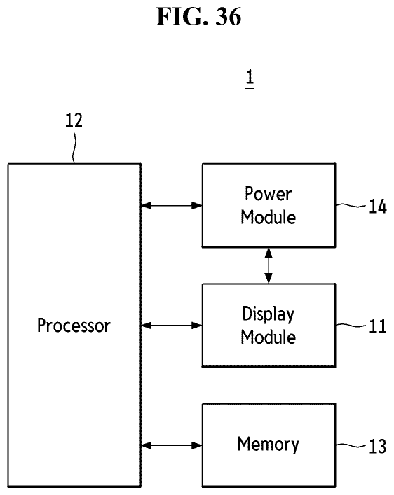

FIG. 36 is a schematic block diagram of an electronic device according to one embodiment of the disclosure.

Referring to FIG. 36, the electronic device 1 according to one embodiment of the disclosure may include a display module 11, a processor 12, a memory 13, and a power module 14.

The processor 12 may include at least one of a central processing unit (CPU), an application processor (AP), a graphic processing unit (GPU), a communication processor (CP), an image signal processor (ISP), and a controller.

The memory 13 may store data information necessary for the operation of the processor 12 or the display module 11. In case that the processor 12 executes an application stored in the memory 13, an image data signal and/or an input control signal is transmitted to the display module 11, and the display module 11 can process the received signal and output image information through a display screen.

The power module 14 may include a power supply module such as, for example a power adapter or a battery, and a power conversion module that converts the power supplied by the power supply module to generate power necessary for the operation of the electronic device 1.

At least one of the components of the electronic device 1 according to the one embodiment of the disclosure may be included in the display device 10 according to the embodiments of the disclosure. Some modules of the individual modules functionally included in one module may be included in the display device 10, and other modules may be provided separately from the display device 10. For example, the display device 10 may include the display module 11, and the processor 12, the memory 13, and the power module 14 may be provided in the form of other devices within the electronic device 1 other than the display device 10.

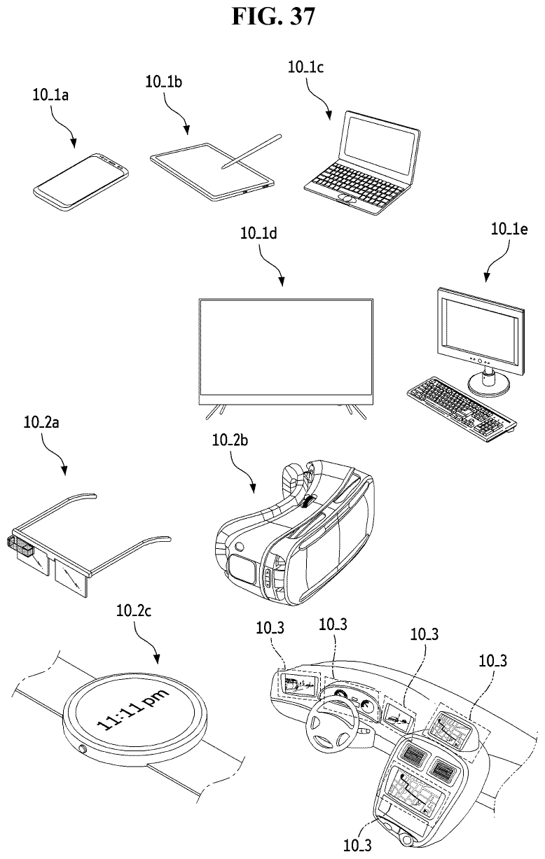

FIG. 37 is a schematic diagram of an electronic device according to various embodiments of the disclosure.

Referring to FIG. 37, various electronic devices to which display devices 10 according to embodiments of the disclosure are applied may include not only image display electronic devices such as a smart phone 10_1a, a tablet PC (personal computer) 10_1b, a laptop 10_1c, a TV 10_1d, and a desk monitor 10_1e, but also wearable electronic devices including display modules such as, for example smart glasses 10_2a, a head mounted display 10_2b, and a smart watch 10_2c, and vehicle electronic devices 10_3 including display modules such as a CID (Center Information Display) and a room mirror display arranged on a dashboard, center fascia, and dashboard of an automobile.

In concluding the detailed description, those skilled in the art will appreciate that many variations and modifications can be made to the preferred embodiments without substantially departing from the principles of the disclosure. Therefore, the disclosed preferred embodiments of the invention are used in a generic and descriptive sense only and not for purposes of limitation.

What is claimed is:

1. A display device comprising:
a light emitting element layer disposed on a substrate;
a thin-film encapsulation layer disposed on the light emitting element layer;
a counter substrate facing the substrate;
a color filter layer disposed on a surface of the counter substrate and having a plurality of light transmitting areas and a light blocking area defined;
a wavelength conversion layer disposed on the color filter layer; and
a filling layer disposed between the wavelength conversion layer and the thin-film encapsulation layer,
wherein the wavelength conversion layer comprises:
a bank overlapping the light blocking area;
a plurality of light transmitting members disposed between portions of the bank and spaced apart from each other; and
organic layers spaced apart from each other with the bank interposed between the organic layers and covering the light transmitting members, and lower surfaces of the organic layers and a lower surface of the bank are disposed on a same layer.

2. The display device of claim 1, wherein the bank and the organic layers contact the filling layer.

3. The display device of claim 1, wherein the organic layers overlap the light transmitting areas and do not overlap the light blocking area.

4. The display device of claim 1, wherein a refractive index of each of the organic layers is about 1.7 or less.

5. The display device of claim 1, wherein the bank is non-hydrophobic.

6. The display device of claim 1, further comprising a first capping layer overlapping the organic layers and the bank.

7. The display device of claim 6, wherein upper surfaces of the organic layers contact the light transmitting members, respectively, and the lower surfaces of the organic layers contact the first capping layer.

8. The display device of claim 6, wherein the first capping layer is formed flat.

9. The display device of claim 6, further comprising a second capping layer disposed between the light transmitting members and the organic layers and covering the light transmitting members.

10. The display device of claim 9, further comprising third capping layers spaced apart from each other with the bank disposed between the third capping layers and extend along side surfaces of the bank.

11. The display device of claim 10, wherein the organic layers are surrounded by the first capping layer and the third capping layers.

12. The display device of claim 1, further comprising first capping layer disposed between the light transmitting members and the organic layers and covering the light transmitting members.

13. The display device of claim 12, wherein the first capping layer is formed in plural, spaced apart from each other with the bank interposed therebetween and extend along side surfaces of the bank.

14. A method of manufacturing a display device, the method comprising:
forming a bank on a first substrate;
forming a hydrophobic layer on an upper surface of the bank by performing an ashing process and a plasma process on the bank;
forming a plurality of light transmitting members between portions of the bank;
forming an organic material layer on the bank and the light transmitting members;
forming organic layers by removing a portion of the organic material layer and the hydrophobic layer;
forming a filling layer on the bank and the organic layers; and
bonding the first substrate to a second substrate facing the first substrate.

15. The method of claim 14, wherein
the ashing process is a plasma treatment process using Ar, N₂, He, O₂, or a mixed gas thereof as a reaction gas and
the plasma process uses a CF₄ gas.

16. The method of claim 14, further comprising:
forming a first capping layer on the bank and the light transmitting members before the forming of the organic material layer,
wherein a portion of the first capping layer is removed at same time as the portion of the organic material layer and the hydrophobic layer are removed.

17. The method of claim 16, further comprising forming a second capping layer on the bank and the organic layers before the forming of the filling layer.

18. The method of claim 14, further comprising forming a color filter layer on the first substrate before the forming of the bank, wherein
the second substrate comprises a light emitting element layer comprising a plurality of light emitting elements and a thin-film encapsulation layer formed on the light emitting element layer, and
the bank is formed on the color filter layer.

19. The method of claim 14, further comprising forming a color filter layer on the second substrate before the forming of the bank, wherein the first substrate comprises a light emitting element layer comprising a plurality of light emitting elements and a thin-film encapsulation layer formed on the light emitting element layer, and the bank is formed on the thin-film encapsulation layer.

20. An electronic device comprising:
a display device which provides an image;
a processor which provides an image data signal to the display device;
a memory which stores a data information for operation; and
a power module which generates power,
wherein the display device comprises:
a light emitting element layer disposed on a substrate;
a thin-film encapsulation layer disposed on the light emitting element layer;
a counter substrate facing the substrate;
a color filter layer disposed on a surface of the counter substrate and having a plurality of light transmitting areas and a light blocking area defined;
a wavelength conversion layer disposed on the color filter layer; and
a filling layer disposed between the wavelength conversion layer and the thin-film encapsulation layer,
wherein the wavelength conversion layer comprises:
a bank overlapping the light blocking area;
a plurality of light transmitting members disposed between portions of the bank and spaced apart from each other; and
organic layers spaced apart from each other with respect to the bank interposed between the organic layers and covering the light transmitting members, and
lower surfaces of the organic layers and a lower surface of the bank are disposed on a same layer.
